(19) United States
(12) Patent Application Publication
(10) Pub. No.: US 2021/0179901 A1
(43) Pub. Date: Jun. 17, 2021

(54) LAYERED BODY FOR FLEXIBLE IMAGE DISPLAY DEVICE, AND FLEXIBLE IMAGE DISPLAY DEVICE

(71) Applicant: NITTO DENKO CORPORATION, Ibaraki-shi, Osaka (JP)

(72) Inventors: Masakuni Fujita, Ibaraki-shi (JP); Yusuke Toyama, Ibaraki-shi (JP); Taiki Shimokuri, Ibaraki-shi (JP)

(73) Assignee: NITTO DENKO CORPORATION, Ibaraki-shi, Osaka (JP)

(21) Appl. No.: 16/635,280

(22) PCT Filed: Jul. 26, 2018
(86) PCT No.: PCT/JP2018/028073

§ 371 Date: Jan. 30, 2020

(30) Foreign Application Priority Data
Jul. 31, 2017 (JP) 2017-148662

(51) Int. Cl. C09J 133/08; C09J 7/38; H01L 51/52; B32B 27/30; B32B 27/36; B32B 27/08; B32B 7/12; B32B 27/16

(52) U.S. Cl. CPC C09J 133/08; C09J 7/385; H01L 51/5281; B32B 27/308; B32B 27/36; B32B 27/08; G02B 5/3025; B32B 27/16; C09J 2301/312; C09J 2301/208; C09J 2203/318; C09J 2433/00; B32B 7/12

(57) ABSTRACT

A laminate for a flexible image display device is disclosed including a pressure-sensitive adhesive layer and an optical film including at least a polarizing membrane, wherein an amount of deviation based on the pressure-sensitive adhesive layer in an end part of the laminate when the laminate is bent with a bending radius of 3 mm is set in a specific range, whereby exposure of the pressure-sensitive adhesive layer in the end part of the laminate with bending can be suppressed. The laminate for a flexible image display device includes a pressure-sensitive adhesive layer and an optical film including at least a polarizing membrane, wherein an amount of deviation based on the pressure-sensitive adhesive layer in an end part of the laminate is 100 to 600 μm when the laminate is bent with a bending radius of 3 mm.

### TECHNICAL FIELD

The present invention relates to a laminate for a flexible image display device, including a pressure-sensitive adhesive layer and an optical film including at least a polarizing membrane; and a flexible image display device in which the laminate for a flexible image display device is arranged.

### BACKGROUND ART

As an organic EL display device integrated with a touch sensor is shown in FIG. 1, an optical laminate 20 is provided on the viewing side of an organic EL display panel 10, and a touch panel 30 is provided on the viewing side of the optical laminate 20. The optical laminate 20 includes a polarizing membrane 1 having protective membranes 2-1 and 2-2 bonded on both sides thereof and a retardation membrane 3, and the polarizing membrane 1 is provided on the viewing side of the retardation membrane 3. Further, in the touch panel 30, transparent conductive films 4-1 and 4-2 having a structure in which substrate films 5-1 and 5-2 and transparent conductive layers 6-1 and 6-2 are laminated are arranged with an interposed spacer 7 (see, for example, Patent Document 1).

In addition, it is expected to realize a foldable organic EL display device which is more excellent in portability.

### PRIOR ART DOCUMENT

### Patent Document

Patent Document 1: JP-A-2014-157745

### SUMMARY OF THE INVENTION

### Problems to be Solved by the Invention

However, the conventional organic EL display device as disclosed in Patent Document 1 is not designed as being folded in mind. When a plastic film is used for an organic EL display panel substrate, bendability can be imparted to the organic EL display panel. In addition, even when the plastic film is used for the touch panel and incorporated in the organic EL display panel, bendability can be imparted to the organic EL display panel. However, a problem arises in that an optical film including a conventional polarizing membrane or the like laminated on the organic EL display panel hinders the bendability of the organic EL display device.

In addition, in the conventional organic EL display device, when repeatedly bent, a slight strain occurs in each layer or between the layers of an optical film and a pressure-sensitive adhesive layer constituting the organic EL display device, so that the pressure-sensitive adhesive layer is deformed to generate a large deviation (difference) occurring in the end part between the outermost layer and the innermost layer in the optical laminate and other layers. Thus, due to display defects at the periphery of the display area in narrow frame or frameless image display devices and exposure of the pressure-sensitive adhesive layer in the end part, a problem that causes quality degradation due to adhesive stain and stickiness may arise. Furthermore, problems such as peeling and cracking (breaking) occur.

The purpose of the present invention is to provide: a laminate for a flexible image display device, the laminate including a pressure-sensitive adhesive layer and an optical film including at least a polarizing membrane, wherein an amount of deviation based on the pressure-sensitive adhesive layer in an end part of the laminate when the laminate is bent with a bending radius of 3 mm is set in a specific range, whereby exposure of the pressure-sensitive adhesive layer in the end part of the laminate can be suppressed with respect to the bending, the laminate has excellent end part quality, and the laminate for a flexible image display device furthermore has excellent bending resistance or adhesiveness and is free of peeling or breakage even from repeated bending; and a flexible image display device in which the laminate for a flexible image display device is arranged.

### Means for Solving the Problems

The laminate for a flexible image display device according to the present invention is a laminate including a pressure-sensitive adhesive layer and an optical film including at least a polarizing membrane and is characterized in that the amount of deviation based on the pressure-sensitive adhesive layer in an end part of the laminate is 100 to 600 μm when the laminate is bent with a bending radius of 3 mm.

In the laminate for a flexible image display device according to the present invention, it is preferable that a storage elastic modulus G′ at 25° C. of the pressure-sensitive adhesive layer is 4×10⁴ to 8×10⁵ Pa.

In the laminate for a flexible image display device according to the present invention, the pressure-sensitive adhesive layer is preferably formed of a pressure-sensitive adhesive composition containing a (meth)acrylic polymer.

In the laminate for a flexible image display device according to the present invention, it is preferable that the laminate has 2 and more and 5 or less layers of the pressure-sensitive adhesive layer.

In the flexible image display device according to the present invention, it is preferable that the device includes the laminate for a flexible image display device and an organic EL display panel, wherein the laminate for a flexible image display device is arranged on a viewing side with respect to the organic EL display panel.

In the flexible image display device according to the present invention, it is preferable that a window is arranged on a viewing side with respect to the laminate for a flexible image display device.

### Effect of the Invention

According to the present invention, it is possible and useful to obtain a laminate for a flexible image display device, including a pressure-sensitive adhesive layer and an optical film including at least a polarizing membrane, wherein an amount of deviation based on the pressure-sensitive adhesive layer in an end part of the laminate when the laminate is bent with a bending radius of 3 mm is set in a specific range, whereby exposure of the pressure-sensitive adhesive layer in the end part of the laminate can be suppressed with respect to the bending, the laminate has excellent end part quality, and the laminate for a flexible image display device furthermore has excellent bending resistance or adhesiveness and is free of peeling or breakage even from repeated bending; and a flexible image display device in which the laminate for a flexible image display device is arranged.

Embodiments of an optical film, a laminate for a flexible image display device, and a flexible image display device according to the present invention will be described in detail below with reference to the drawings and the like.

### BRIEF DESCRIPTION OF THE DRAWINGS

FIG. 1 is a cross-sectional view showing a conventional organic EL display device.

FIG. 2 is a cross-sectional view showing a flexible image display device according to an embodiment of the present invention.

FIG. 3 is a cross-sectional view showing a flexible image display device according to another embodiment of the present invention.

FIG. 4 is a cross-sectional view showing a flexible image display device according to another embodiment of the present invention.

FIG. 5 is a view showing a bending test ((A) bending angle 0°, (B) bending angle 180°).

FIG. 6 is a cross-sectional view showing a sample for evaluation used in Examples.

FIG. 7 is a view showing a method of producing a retardation used in Examples.

FIG. 8 is a view showing a method for measuring an amount of deviation based on a plurality of pressure-sensitive adhesive layers constituting the laminate for a flexible image display device in the end part of the laminate for a flexible image display device.

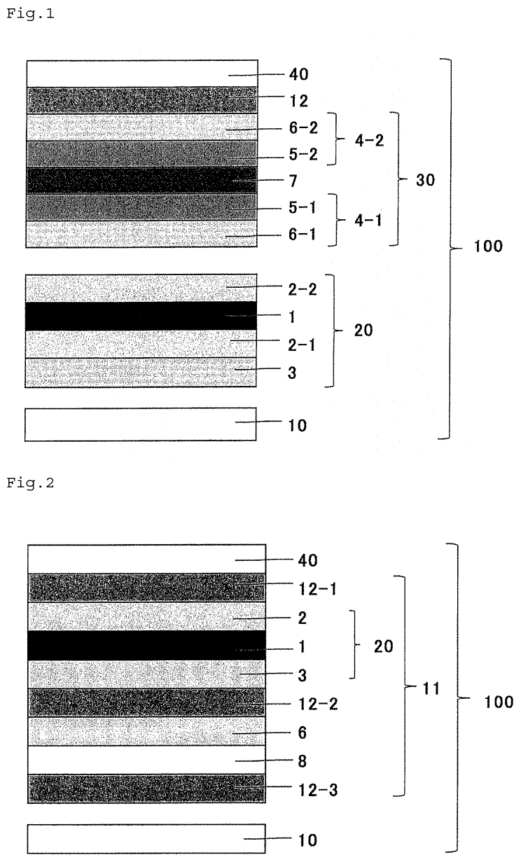

### MODE FOR CARRYING OUT THE INVENTION

Hereinafter, the present invention will be described in detail. However, the present invention is not limited to the following embodiments and can be carried out with arbitrary modification without departing from the gist of the present invention.

### [Laminate for Flexible Image Display Device]

The laminate for a flexible image display device according to the present invention is characterized by including a pressure-sensitive adhesive layer and an optical film including at least a polarizing membrane.

### [Optical Film]

The laminate for a flexible image display device according to the present invention is characterized by including an optical film including at least a polarizing membrane, and the optical film may refer to, in addition to the polarizing membrane, for example, a film such as a protective membrane and a retardation membrane formed of a transparent resin material. Further, in the present invention, an optical laminate has a configuration such that the optical film includes the polarizing membrane, a protective membrane made of a transparent resin material on the first surface of the polarizing membrane, and a retardation membrane on a second surface different from the first surface of the polarizing membrane. Note that the optical film does not include a pressure-sensitive adhesive layer such as a first pressure-sensitive adhesive layer described later.

The thickness of the optical film is preferably 92 μm or less, more preferably 60 μm or less, still more preferably 10 to 50 μm. Within the above range, a preferred embodiment is obtained without hindering the bending of the optical film.

As long as the properties of the present invention are not impaired, a protective membrane may be bonded to at least one side of the polarizing membrane with an adhesive (layer) (not shown in the drawing). An adhesive can be used for the adhesion treatment of the polarizing membrane and the protective membrane. Examples of the adhesive include isocyanate-based adhesives, polyvinyl alcohol-based adhesives, gelatin-based adhesives, vinyl-based latex adhesives, aqueous polyester adhesives and the like. The adhesive is usually used as an adhesive made of an aqueous solution, and usually contains 0.5 to 60% by weight of a solid content. Besides the above, as an adhesive between the polarizing membrane and the protective membrane, an ultraviolet curable type adhesive, an electron beam-curable type adhesive and the like can be exemplified. The adhesive for electron beam-curable type polarizing film shows a suitable adhesiveness to the various protective membranes mentioned above. The adhesive used in the present invention may contain a metal compound filler. In the present invention, those obtained by laminating a polarizing membrane and a protective membrane with an adhesive (layer) may be sometimes referred to as a polarizing film (polarizing plate).

### <Polarizing Membrane>

In the polarizing membrane (also referred to as a polarizer) contained in the optical film of the present invention, it is possible to use a polyvinyl alcohol (PVA)-based resin which is stretched by a stretching step such as an in-air stretching (dry stretching) and a stretching in an aqueous boric acid and in which iodine is aligned.

Typically, as a method for producing the polarizing membrane, there is a manufacturing method including a step of dyeing a single layer body of a PVA-based resin and a step of stretching the dyed single layer body as described in JP-A-2004-341515 (a monolayer stretching method). In addition, as described in JP-A-51-069644, JP-A-2000-338329, JP-A-2001-343521, WO 2010/100917, JP-A-2012-073563, and JP-A-2011-2816, there is exemplified a production method including a step of stretching a PVA-based resin layer and a stretching resin substrate in the state of a laminate and a step of dyeing the laminate. According to this production method, even when the PVA-based resin layer is thin, the resin layer can be stretched without inconveniences such as breakage due to stretching because such resin layer is supported by the stretching resin substrate.

As the production method including a step of stretching in the state of a laminate and a step of dyeing the laminate, an air stretching (dry stretching) method described in JP-A-51-069644, JP-A-2000-338329, or JP-A-2001-343521 is exemplified. From the viewpoint of being able to stretching to a high draw ratio and improve the polarization performance, a production method including a step of stretching in an aqueous boric acid solution as described in WO 2010/100917 A and JP-A-2012-073563 is preferable, and a production method (two-step stretching method) including a step of performing aerial sub-stretching before stretching in an aqueous boric acid solution as described in JP-A-2012-073563 is particularly preferable. In addition, as described in JP-A-2011-2816, a method of stretching a PVA-based resin layer and a stretching resin substrate in a laminate state, excessively dyeing the PVA-based resin layer, and then decoloring the dyed resin layer (excess dyeing decolorization method) is also preferable. The polarizing membrane contained in the optical film of the present invention can be made of a polyvinyl alcohol-based resin in which iodine is aligned as described above, and such a polarizing membrane can be obtained by stretching in a two-step stretching step comprising aerial sub-stretching and stretching in an aqueous boric acid solution. The polarizing membrane is made of the polyvinyl alcohol-based resin in which iodine is aligned as described above and can be produced by excessively dyeing the laminate of the stretched PVA-based resin layer and the stretchable resin substrate, and then decolorizing the laminate.

The thickness of the polarizing membrane is 20 μm or less, preferably 12 μm or less, more preferably 9 μm or less, still more preferably 1 to 8 μm, particularly preferably 3 to 6 μm. A preferred embodiment is within the above range without hindering the bending of the polarizing membrane.

### <Retardation Membrane>

The optical film used in the present invention can include a retardation membrane, and it is possible to use a retardation membrane (also referred to as a retardation film) obtained by stretching a polymer film or aligning and fixing a liquid crystal material. In the present specification, the retardation membrane refers to a film having birefringence in the plane direction and/or in the thickness direction.

Examples of the retardation membrane may include an anti-reflection retardation membrane (see paragraphs [0221], [0222], and [0228] in JP-A-2012-133303), a viewing-angle compensating retardation membrane (see paragraphs [0225] and [0226] in JP-A-2012-133303), and a viewing-angle compensating obliquely-aligned retardation membrane (see paragraph [0227] in JP-A-2012-133303).

Any known retardation membrane substantially having any of the functions described above can be used irrespective of, for example, the retardation value, the arrangement angle, the three-dimensional birefringence index, whether or not a single layer or a multilayer, and other factors.

The thickness of the retardation membrane is preferably 20 μm or less, more preferably 10 μm or less, still more preferably 1 to 9 μm, and especially preferably 3 to 8 μm or less. Within the above range of the thickness of the retardation membrane, a preferred embodiment is obtained without hindering the bending of the retardation membrane.

### <Protective Membrane>

The optical film used in the present invention can include a protective membrane formed from a transparent resin material, and as the protective membrane (also referred to as a transparent protective film), a cycloolefin-based resin such as a norbornene resin, an olefin-based resin such as polyethylene and polypropylene, a polyester-based resin, a (meth)acrylic resin or the like can be used.

The thickness of the protective membrane is preferably 5 to 60 μm, more preferably 10 to 40 μm, still more preferably 10 to 30 μm, and a surface treatment layer, such as an anti-glare layer and an antireflection layer, may be provided as appropriate. Within the above range, a preferred embodiment is obtained without hindering the bending of the protective membrane.

### [Pressure-Sensitive Adhesive Layer]

The laminate for a flexible image display device according to the present invention is a laminate for a flexible image display device, the laminate being characterized by including a pressure-sensitive adhesive layer and an optical film including at least a polarizing membrane. The pressure-sensitive adhesive layer may be a single layer, or may have 2 or more layers for laminating a transparent conductive film, an organic EL display panel, a window, a decorative printing film, a retardation layer, a protective membrane or the like in addition to the optical film (for example, see FIG. 2 and the like as a case where a plurality of pressure-sensitive adhesive layers such as a first pressure-sensitive adhesive layer and a second pressure-sensitive adhesive layer are provided in the laminate for a flexible image display device). When a plurality of pressure-sensitive adhesive layers is provided, it is preferable to provide 2 or more layers and 5 or less layers. When the number of the pressure-sensitive adhesive layers is more than five, the thickness of the entire laminate is increased, so that the difference in a strain between the outermost layer and the innermost layer in the bent portion of the laminate is increased, resulting in being likely to cause the occurrence of peeling or breaking. This is not preferable.

### [First Pressure-Sensitive Adhesive Layer]

Among the pressure-sensitive adhesive layers used in the laminate for a flexible image display device according to the present invention, the first pressure-sensitive adhesive layer is preferably arranged on the side opposite to the surface in contact with the polarizing membrane with respect to the protective membrane (see FIG. 2).

The pressure-sensitive adhesive layer forming the first pressure-sensitive adhesive layer used in the laminate for a flexible image display device according to the present invention is preferably an acrylic pressure-sensitive adhesive, a rubber-based pressure-sensitive adhesive, a vinyl alkyl ether-based pressure-sensitive adhesive, a silicone-based pressure-sensitive adhesive, a polyester-based resin pressure-adhesive, a polyamide-based pressure-sensitive adhesive, an urethane-based pressure-sensitive adhesive, a fluorine-based pressure-sensitive adhesive, an epoxy-based pressure-sensitive adhesive, a polyether-based pressure-sensitive adhesive and the like. The pressure-sensitive adhesive forming the above-mentioned pressure-sensitive adhesive layer may be used alone or in combination of two or more kinds thereof. However, from the viewpoints of transparency, processability, durability, adhesiveness, bending resistance, etc., it is preferable to use an acrylic pressure-sensitive adhesive (composition) containing a (meth)acrylic polymer alone.

### <(Meth)Acrylic Polymer>

When an acrylic pressure-sensitive adhesive is used as the pressure-sensitive adhesive composition, a (meth)acrylic polymer containing, as a monomer unit, a (meth)acrylic monomer having a linear or branched alkyl group of 1 to 30 carbon atoms is preferably contained in the composition. By using the (meth)acrylic monomer having a linear or branched alkyl group of 1 to 30 carbon atoms, a pressure-sensitive adhesive layer excellent in bendability can be obtained. In the present invention, the term “(meth)acrylic polymer” refers to an acrylic polymer and/or a methacrylic polymer, and the term “(meth)acrylate” refers to an acrylate and/or a methacrylate.

Specific examples of the (meth)acrylic monomer having a linear or branched alkyl group of 1 to 30 carbon atoms forming the main skeleton of the (meth)acrylic polymer include methyl (meth)acrylate, ethyl (meth)acrylate, n-butyl (meth)acrylate, s-butyl (meth)acrylate, t-butyl (meth)acrylate, isobutyl (meth)acrylate, n-pentyl (meth)acrylate, isopentyl (meth)acrylate, n-hexyl (meth)acrylate, isohexyl (meth)acrylate, isoheptyl (meth)acrylate, 2-ethylhexyl (meth)acrylate, n-octyl (meth)acrylate, isooctyl (meth)acrylate, n-nonyl (meth)acrylate, isononyl (meth)acrylate, n-decyl (meth)acrylate, isodecyl (meth)acrylate, n-dodecyl (meth)acrylate (lauryl (meth)acrylate), n-tridecyl (meth)acrylate, n-tetradecyl (meth)acrylate, etc. Among them, a (meth)acrylic monomer having a linear or branched alkyl group of 4 to 12 carbon atoms is preferred from the viewpoint of establishing compatibility between reduction in the amount of deviation based on the pressure-sensitive adhesive layer and bendability in the end part of the laminate. By using the (meth)acrylic monomer having an alkyl group of 4 to 12 carbon atoms, entanglement of the polymer is moderately controlled, and the amount of deviation can be controlled within a preferable range with respect to minute strains. This is a preferred embodiment for establishing compatibility between the end part quality and bendability. As the (meth)acrylic monomer, one or two or more kinds thereof can be used. In the laminate for a flexible image display device, “minute strain” indicates, for example, a strain of about ±0 to 10% with respect to a bending direction of 3 mm centered on the apex of the bent portion, and “+” indicates a strain in the tensile direction and “−” indicates a strain in the compression direction. Usually, a tensile-direction strain of “+” is applied to the outer side of the bend (convex side), a compression-direction strain of “−” is applied to the inner side of the bend (concave side), and any of the inside of the laminate to be bent has a neutral axis where the strain stress is zero.

The linear or branched (meth)acrylic monomer having an alkyl group of 1 to 30 carbon atoms is a main component in all the monomers forming the (meth)acrylic polymer. Here, as the main component, the total amount of (meth)acrylic monomer having a linear or branched alkyl group of 1 to 30 carbon atoms in all the monomers constituting the (meth)acrylic polymer is preferably from 50 to 100% by weight, more preferably from 80 to 100% by weight, still more preferably from 90 to 99.9% by weight, particularly preferably from 94 to 99.9% by weight.

The monomer component constituting the (meth)acrylic polymer may include a monomer that can be copolymerized (copolymerizable monomer) other than the (meth)acrylic monomer having a linear or branched alkyl group of 1 to 30 carbon atoms. In addition, the copolymerizable monomer may be used alone or in combination of two or more kinds thereof.

Although the copolymerizable monomer is not particularly limited, it is preferable to contain a (meth)acrylic-polymer including [symbol] a hydroxyl group-containing monomer having a reactive functional group. By using the hydroxyl group-containing monomer, a pressure-sensitive adhesive layer excellent in adhesiveness and bendability can be obtained. The hydroxyl group-containing monomer contains a hydroxyl group in its structure and is a compound containing a polymerizable unsaturated double bond such as a (meth)acryloyl group or a vinyl group.

Specific examples of the hydroxyl group-containing monomer include hydroxyalkyl (meth)acrylates (e.g. 2-hydroxyethyl (meth)acrylate, 3-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, etc.) and (4-hydroxymethylcyclohexyl)-methyl acrylate. Among the hydroxyl group-containing monomers, 2-hydroxyethyl (meth)acrylate and 4-hydroxybutyl (meth)acrylate are preferable from the viewpoints of durability and adhesiveness. One or two or more kinds of the hydroxyl group-containing monomers may be used.

In addition, as the copolymerizable monomer, it is possible to contain a monomer having a reactive functional group, such as a carboxyl group-containing monomer, an amino group-containing monomer, and an amide group-containing monomer. It is preferable to use these monomers from the viewpoint of adhesiveness under humidification and high temperature environments.

When an acrylic pressure-sensitive adhesive is used as the pressure-sensitive adhesive composition, a (meth)acrylic polymer containing a carboxyl group-containing monomer having a reactive functional group can be contained as a monomer unit. By using the carboxyl group-containing monomer, it is possible to obtain a pressure-sensitive adhesive layer having an excellent adhesiveness under humidification and high temperature environments. The carboxyl group-containing monomer is a compound containing a carboxyl group and a polymerizable unsaturated double bond such as a (meth)acryloyl group and a vinyl group in its structure.

Specific examples of the carboxyl group-containing monomer include (meth)acrylic acid, carboxyethyl (meth)acrylate, carboxypentyl (meth)acrylate, itaconic acid, maleic acid, fumaric acid, crotonic acid, and the like.

When an acrylic pressure-sensitive adhesive is used as the pressure-sensitive adhesive composition, a (meth)acrylic polymer containing an amino group-containing monomer having a reactive functional group can be contained as a monomer unit. By using the amino group-containing monomer, it is possible to obtain a pressure-sensitive adhesive layer having an excellent adhesiveness under humidification and high temperature environments. The amino group-containing monomer is a compound containing an amino group as well as a polymerizable unsaturated double bond such as a (meth)acryloyl group, a vinyl group or the like in its structure.

Specific examples of the amino group-containing monomer include N,N-dimethylaminoethyl (meth)acrylate, N,N-dimethylaminopropyl (meth)acrylate, and the like.

When an acrylic pressure-sensitive adhesive is used as the pressure-sensitive adhesive composition, a (meth)acrylic polymer containing an amide group-containing monomer having a reactive functional group as a monomer unit can be contained. By using the amide group-containing monomer, a pressure-sensitive adhesive layer having an excellent adhesiveness can be obtained. The amide group-containing monomer is a compound containing an amide group in its structure and a polymerizable unsaturated double bond such as a (meth)acryloyl group or a vinyl group.

Specific examples of the amide group-containing monomer include acrylamide-based monomers such as (meth)acrylamide, N,N-dimethyl (meth)acrylamide, N,N-diethyl (meth)acrylamide, N-isopropylacrylamide, N-methyl (meth)acrylamide, N-butyl (meth)acrylamide, N-hexyl (meth)acrylamide, N-methylol (meth)acrylamide, N-methylol-N-propane (meth)acrylamide, aminomethyl (meth)acrylamide, aminoethyl (meth)acrylamide, mercaptomethyl (meth)acrylamide, and mercaptoethyl (meth)acrylamide; N-acryloyl heterocyclic monomers such as N-(meth)acryloyl morpholine, N-(meth)acryloyl piperidine, and N-(meth)acryloyl pyrrolidine; N-vinyl group-containing lactam-based monomers such as N-vinylpyrrolidone and N-vinyl-ε-caprolactam; and the like.

Furthermore, examples of the copolymerizable monomer include polyfunctional monomers (multifunctional monomers). When the polyfunctional monomer is contained, a crosslinking effect is obtained by polymerization, and the gel fraction can be easily adjusted and the cohesive force can be easily improved. For this reason, cutting becomes easy and workability is improved. Further, peeling due to cohesive failure of the pressure-sensitive adhesive layer can be prevented during bending (particularly in a high temperature environment). The polyfunctional monomer is not particularly limited, and examples thereof include, for example, polyfunctional acrylates such as hexanediol di(meth)acrylate (1,6-hexanediol di(meth)acrylate), butanediol di(meth)acrylate, (poly)ethylene glycol di(meth)acrylate, (poly) propylene glycol di(meth)acrylate, neopentyl glycol di(meth)acrylate, pentaerythritol di(meth)acrylate, pentaerythritol tri(meth)acrylate, dipentaerythritol hexa(meth)acrylate, trimethylolpropane tri(meth)acrylate, tetramethylolmethane tri(meth)acrylate, allyl (meth)acrylate, vinyl (meth)acrylate, epoxy acrylate, polyester acrylate, and urethane acrylate; and divinylbenzene; and the like. In particular, 1,6-hexanediol diacrylate and dipentaerythritol hexa(meth)acrylate is preferably used as the polyfunctional acrylate. The polyfunctional monomer may be used alone or in combination of two or more kinds thereof.

As a monomer unit forming the (meth)acrylic polymer, the blending ratio (total amount) of the monomer having a reactive functional group and the polyfunctional monomer is preferably 20% by weight or less in the total monomers forming the (meth)acrylic polymer, more preferably 10% by weight or less, still more preferably 0.01 to 8% by weight, particularly preferably 0.01 to 5% by weight, most preferably 0.05 to 3% by weight. When such blending ratio exceeds 20% by weight, the number of crosslinking points increases and the flexibility of the pressure-sensitive adhesive (layer) is lost, so that a stress relaxation property tends to be poor.

When an acrylic pressure-sensitive adhesive is used as the pressure-sensitive adhesive composition, other copolymerization monomer can be introduced as a monomer unit within the range not impairing the effects of the present invention, in addition to the monomer having a reactive functional group and the polyfunctional monomer.

Examples of the other copolymerization monomers include (meth)acrylic acid alkoxyalkyl esters [for example, 2-methoxyethyl (meth)acrylate, 2-ethoxyethyl (meth)acrylate, methoxytriethylene glycol (meth)acrylate, 3-methoxypropyl (meth)acrylate, 3-ethoxypropyl (meth)acrylate, 4-methoxybutyl (meth)acrylate, 4-ethoxybutyl (meth)acrylate, etc.]; epoxy group-containing monomers [for example, glycidyl (meth)acrylate, methyl glycidyl (meth)acrylate, etc.]; sulfonic acid group-containing monomers [for example, sodium vinyl sulfonate]; phosphoric acid group-containing monomers; (meth)acrylic acid esters having an alicyclic hydrocarbon group [for example, cyclopentyl (meth)acrylate, cyclohexyl (meth)acrylate, isobornyl (meth)acrylate, etc.]; (meth)acrylic acid esters having an aromatic hydrocarbon group [for example, phenyl (meth)acrylate, phenoxyethyl (meth)acrylate, benzyl (meth)acrylate, etc.]; vinyl esters [for example, vinyl acetate, vinyl propionate, etc.]; aromatic vinyl compounds [for example, styrene, vinyl toluene, etc.]; olefins or dienes [for example, ethylene, propylene, butadiene, isoprene, isobutylene, etc.]; vinyl ethers [for example, vinyl alkyl ether, etc.]; vinyl chloride; and the like.

The blending ratio of the other copolymerizable monomer is not particularly limited but is preferably 30% by weight or less, more preferably 10% by weight or less, with respect to all the monomers forming the (meth)acrylic polymer, and it is still more preferable not to contain the other copolymerizable monomers. When the blending ratio exceeds 30% by weight, in particular when a monomer other than the (meth)acrylic monomer is used, the reaction points between the pressure-sensitive adhesive layer and other layers (film, substrate) are reduced, and the adhesion tends to decrease.

The pressure-sensitive adhesive layer is made of a pressure-sensitive adhesive composition. The pressure-sensitive adhesive composition may be in any form. The form is, for example, an emulsion type, a solvent type (solution type), an active energy ray curable type, a heat melting type (hot melt type) and the like. Especially, as the pressure-sensitive adhesive composition, a solvent-type pressure-sensitive adhesive composition and an active energy ray curable-type pressure-sensitive adhesive composition are preferably exemplified.

Preferred examples of the solvent-type pressure-sensitive adhesive composition include a pressure-sensitive adhesive composition containing the (meth)acrylic polymer as an essential component. The active energy ray-curable pressure-sensitive adhesive composition is preferably a pressure-sensitive adhesive composition containing, as an essential component, a mixture of monomer components (monomer mixture) constituting the (meth)acrylic polymer or a partially polymerized product thereof. Note that the “partially polymerized product thereof” means a composition in which one or more components among the monomer components contained in the monomer mixture are partially polymerized. In addition, the “monomer mixture” includes a case where there is only one monomer component.

In particular, the pressure-sensitive adhesive composition is preferably an active energy ray-curable pressure-sensitive adhesive composition containing, as an essential component, a mixture of monomer components (monomer mixture) constituting a (meth)acrylic polymer or a partially polymerized product thereof, from the viewpoints of productivity, environmental impact, and ease of obtaining thick pressure-sensitive adhesive layers.

The (meth)acrylic polymer can be obtained by polymerizing the monomer component. More specifically, the (meth)acrylic polymer can be obtained by polymerizing the monomer component, the monomer mixture or a partially polymerized product thereof by a known and usual method. Examples of the polymerization method include solution polymerization, emulsion polymerization, bulk polymerization, polymerization by heat or active energy ray irradiation (thermal polymerization, active energy ray polymerization), and the like. Among these, solution polymerization and active energy ray polymerization are preferable in terms of transparency, water resistance, cost, and the like. In addition, it is preferable to carry out the polymerization by avoiding a contact with oxygen from the viewpoint of suppressing the polymerization inhibition caused by oxygen. For example, it is preferable to perform the polymerization in a nitrogen atmosphere, or to perform the polymerization by blocking oxygen with use of a release film (separator). Further, the (meth)acrylic polymer obtained may be any of a random copolymer, a block copolymer, a graft copolymer, and the like.

Examples of the active energy rays irradiated in the active energy ray polymerization (photopolymerization) include ionizing radiation such as α rays, ρ rays, γ rays, neutron rays, and electron rays, and ultraviolet rays, and particularly ultraviolet rays are preferred. The radiation energy, the radiation period, and the radiation method of the active energy rays are not particularly limited, and it is sufficient for these factors to make it possible to activate the photopolymerization initiator to generate a reaction between the monomer components.

In the solution polymerization, various common solvents can be used. Examples of such solvents include organic solvents such as esters (e.g. ethyl acetate, n-butyl acetate, etc.); aromatic hydrocarbons (e.g. toluene, benzene, etc.); aliphatic hydrocarbons (e.g. n-hexane, n-heptane, etc.); alicyclic hydrocarbons (e.g. cyclohexane, methyl cyclohexane, et.); and ketones (e.g. methyl ethyl ketone, methyl isobutyl ketone, etc.). In addition, these solvents may be used alone or in combination of two or more kinds thereof.

In the polymerization, a polymerization initiator such as a photopolymerization initiator (photoinitiator) or a thermal polymerization initiator may be used depending on the type of polymerization reaction. In addition, these polymerization initiators may be used alone or in combination of two or more kinds thereof.

The photopolymerization initiator is not particularly limited, and examples thereof include benzoin ether-based photopolymerization initiators, acetophenone-based photopolymerization initiators, α-ketol-based photopolymerization initiators, aromatic sulfonyl chloride-based photopolymerization initiators, photoactive oxime-based photopolymerization initiators, benzoin-based photopolymerization initiators, benzyl-based photopolymerization initiators, benzophenone-based photopolymerization initiators, ketal-based photopolymerization initiators, thioxanthone-based photopolymerization initiators, and the like.

Examples of the benzoin ether-based photopolymerization initiators include benzoin methyl ether, benzoin ethyl ether, benzoin propyl ether, benzoin isopropyl ether, benzoin isobutyl ether, 2,2-dimethoxy-1,2-diphenylethan-1-one, anisole methyl ether, and the like. Examples of the acetophenone-based photopolymerization initiators include 2,2-diethoxyacetophenone, 2,2-dimethoxy-2-phenylacetophenone, 1-hydroxycyclohexyl phenyl ketone, 4-phenoxydichloroacetophenone, 4-(t-butyl)dichloro-acetophenone, and the like. Examples of the α-ketol-based photopolymerization initiators include 2-methyl-2-hydroxypropiophenone, 1-[4-(2-hydroxyethyl)phenyl]-2-methylpropan-1-one, and the like. Examples of the aromatic sulfonyl chloride-based photopolymerization initiators include 2-naphthalene sulfonyl chloride and the like. Examples of the photoactive oxime-based photopolymerization initiators include 1-phenyl-1,1-propanedione-2-(o-ethoxycarbonyl)-oxime and the like. Examples of the benzoin-based photopolymerization initiators include benzoin and the like. Examples of the benzyl-based photopolymerization initiators include benzyl and the like. Examples of the benzophenone-based photopolymerization initiators include benzophenone, benzoylbenzoic acid, 3,3′-dimethyl-4-methoxybenzophenone, polyvinylbenzophenone, α-hydroxycyclohexyl phenyl ketone, and the like. Examples of the ketal-based photopolymerization initiators include benzyl dimethyl ketal and the like. Examples of the thioxanthone-based photopolymerization initiators include thioxanthone, 2-chlorothioxanthone, 2-methylthioxanthone, 2,4-dimethylthioxanthone, isopropylthioxanthone, 2,4-diisopropylthioxanthone, dodecylthioxanthone, and the like.

The amount of the photopolymerization initiator to be used is not particularly limited and can be preferably 0.01 to 1 part by weight, more preferably 0.05 to 0.5 parts by weight, with respect to 100 parts by weight of all the monomer components.

Examples of the polymerization initiator used in the solution polymerization include azo-based polymerization initiators, peroxide-based polymerization initiators (e.g. dibenzoyl peroxide, tert-butyl permaleate, etc.), redox-based polymerization initiators, and the like. Of these, the azo-based polymerization initiators disclosed in JP-A-2002-69411 are preferable. Examples of the azo-based polymerization initiator include 2,2′-azobisisobutyronitrile (AIBN), 2,2′-azobis-2-methylbutyronitrile, dimethyl 2,2′-azobis(2-methylpropionate), 4,4′-azobis-4-cyanovaleric acid and the like.

The amount of the azo-based polymerization initiator used is not particularly limited, but is preferably 0.05 to 0.5 parts by weight, more preferably 0.1 to 0.3 parts by weight, with respect to 100 parts by weight of the total amount of the monomer components.

In addition, the polyfunctional monomer (polyfunctional acrylate) used as the copolymerization monomer can be also used for a solvent-type pressure-sensitive adhesive composition or an active energy ray-curable type pressure-sensitive adhesive composition. For example, when the polyfunctional monomer (polyfunctional acrylate) and the photopolymerization initiator are mixed for use in the solvent-based pressure-sensitive adhesive composition, active energy ray curing is performed after heat drying.

In the present invention, the (meth)acrylic polymer used in the solvent-type pressure-sensitive adhesive composition usually has a weight average molecular weight (Mw) in the range of 1 million to 3 million. In consideration of durability, particularly heat resistance, bendability, and control of the amount of deviation of the pressure-sensitive adhesive layer, the weight average molecular weight is preferably 1.4 million or more, and more preferably 1.8 million or more. Further, the weight average molecular weight is preferably 2.5 million or less, and more preferably 2 million or less. When the weight average molecular weight is less than 1 million, the crosslinking points are more increased at the time of crosslinking the polymer chains with each other in order to ensure durability, compared with the (meth)acrylic polymer having a weight average molecular weight of 1 million or more, thereby to lose the flexibility of the pressure-sensitive adhesive (layer). Thus, the strains on the outside of the bend (convex side) and on the inside of the bend (concave side) occurring between each layer (each film) during bending cannot be alleviated, and as a result, breakage of each layer is likely to occur. Further, if the weight average molecular weight is larger than 3 million, a large amount of a diluent solvent is required to adjust the viscosity for coating, and this is not preferable because of an increased cost. In addition, since entanglement between polymer chains of the obtained (meth)acrylic polymer becomes complicated, the flexibility is inferior and breakage of each layer (film) tends to occur during bending. The weight average molecular weight (Mw) is a value measured by GPC (gel permeation chromatography) and calculated in terms of polystyrene.

### <(Meth)Acrylic Oligomer>

The pressure-sensitive adhesive composition can contain a (meth)acrylic oligomer. The (meth)acrylic oligomer is preferably a polymer having a weight average molecular weight (Mw) smaller than that of the (meth)acrylic polymer. By using such a (meth)acrylic oligomer, the (meth)acrylic oligomer is interposed between the acrylic polymers, so that the entanglement of the (meth)acrylic polymer is reduced, and it becomes easy to be deformed with respect to a minute strain. This is a preferred embodiment for bendability.

Examples of the monomer constituting the (meth)acrylic oligomer include alkyl (meth)acrylates such as methyl (meth)acrylate, ethyl (meth)acrylate, propyl (meth)acrylate, isopropyl (meth)acrylate, butyl (meth)acrylate, isobutyl (meth)acrylate, s-butyl (meth)acrylate, t-butyl (meth)acrylate, pentyl (meth)acrylate, isopentyl (meth)acrylate, hexyl (meth)acrylate, 2-ethylhexyl (meth)acrylate, heptyl (meth)acrylate, octyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, and dodecyl (meth)acrylate; esters of (meth)acrylic acid with alicyclic alcohol, such as cyclohexyl (meth)acrylate, isobornyl (meth)acrylate, and dicyclopentanyl (meth)acrylate; aryl (meth)acrylates such as phenyl (meth)acrylate and benzyl (meth)acrylate; (meth)acrylates obtained from alcohols of terpene compound derivatives; and the like. Such (meth)acrylates can be used alone or in combination of two or more kinds thereof.

Typical examples of the (meth)acrylic oligomer include alkyl (meth)acrylates in which an alkyl group such as isobutyl (meth)acrylate and t-butyl (meth)acrylate has a branched structure; esters of (meth)acrylic acid and an alicyclic alcohol, such as cyclohexyl (meth)acrylate, isobornyl (meth)acrylate, and dicyclopentanyl (meth)acrylate; and (meth)acrylates each having a cyclic structure such as aryl (meth)acrylate (e.g. phenyl (meth)acrylate, benzyl (meth)acrylate, etc.). These oligomers preferably contain an acrylic monomer having a relatively bulky structure as a monomer unit. By causing the (meth)acrylic oligomer to have such a bulky structure, the pressure-sensitive adhesive layer can be further improved in adhesion property. In particular, those having a cyclic structure in terms of bulkiness are highly effective, and those having a plurality of rings are more effective. In addition, when ultraviolet rays are employed in the synthesis of (meth)acrylic oligomers or in the production of a pressure-sensitive adhesive layer, those having a saturated bond are preferred in that they are less likely to cause polymerization inhibition. An alkyl (meth)acrylate having a branched alkyl structure or an ester with an alicyclic alcohol can be suitably used as a monomer constituting the (meth)acrylic oligomer.

From such a viewpoint, preferred examples of the (meth)acrylic oligomer include a copolymer made from butyl acrylate (BA), methyl acrylate (MA) and acrylic acid (AA), a copolymer made from cyclohexyl methacrylate (CHMA) and isobutyl methacrylate (IBMA), a copolymer made from cyclohexyl methacrylate (CHMA) and isobornyl methacrylate (IBXMA), a copolymer made from cyclohexyl methacrylate (CHMA) and acryloylmorpholine (ACMO), a copolymer made from cyclohexyl methacrylate (CHMA) and diethyl acrylamide (DEAA), a copolymer made from 1-adamantyl acrylate (ADA) and methyl methacrylate (MMA), a copolymer made from dicyclopentanyl methacrylate (DCPMA) and isobornyl methacrylate (IBXMA), and a copolymer made from dicyclopentanyl methacrylate (DCPMA), cyclohexyl methacrylate (CHMA), isobornyl methacrylate (IBXMA), isobornyl acrylate (IBXA), cyclopentanyl methacrylate (DCPMA), and methyl methacrylate (MMA); and respective homopolymers made from dicyclopentanyl acrylate (DCPA), 1-adamantyl methacrylate (ADMA), or 1-adamantyl acrylate (ADA).

As the polymerization method of the (meth)acrylic oligomer, as with the (meth)acrylic polymer, solution polymerization, emulsion polymerization, bulk polymerization, emulsion polymerization, polymerization by heat or active energy ray irradiation (thermal polymerization, active energy ray polymerization), and the like are exemplified. Among these, solution polymerization and active energy ray polymerization are preferable in view of transparency, water resistance, cost, and the like. Further, the (meth)acrylic oligomer obtained may be any of a random copolymer, a block copolymer, a graft copolymer, and the like.

The (meth)acrylic oligomer can be used in the solvent-type pressure-sensitive adhesive composition and the active energy ray-curable pressure-sensitive adhesive composition in the same manner as the (meth)acrylic polymer. For example, as the active energy ray-curable pressure-sensitive adhesive composition, the (meth)acrylic oligomer is further added to a mixture of monomer components (monomer mixture) constituting the (meth)acrylic polymer or a partially polymerized product thereof. When the (meth)acrylic oligomer is dissolved in a solvent, a pressure-sensitive adhesive layer can be obtained by completing the active energy ray curing after the solvent is removed by heat drying the pressure-sensitive adhesive composition.

The weight average molecular weight (Mw) of the (meth)acrylic oligomer used in the solvent-type pressure-sensitive adhesive composition is preferably 1000 or more, more preferably 2000 or more, still more preferably 3000 or more, and particularly preferably 4000 or more. The weight average molecular weight (Mw) of the (meth)acrylic oligomer is preferably 30,000 or less, more preferably 15,000 or less, still more preferably 10,000 or less, and particularly preferably 7,000 or less. By adjusting the weight average molecular weight (Mw) of the (meth)acrylic oligomer within the above range, for example, when used in combination with the (meth)acrylic polymer, the (meth)acrylic oligomers are interposed between the (meth)acrylic polymers, so that the entanglement of the (meth)acrylic polymers is reduced and the pressure-sensitive adhesive layer is easily deformed with respect to minute strains. Thus, the strain applied to other layers can be reduced, and it is possible to suppress cracking of each layer and peeling between the pressure-sensitive adhesive layer and other layers, which is a preferable embodiment. In addition, the weight average molecular weight (Mw) of the (meth)acrylic oligomer is a value which was measured by gel permeation chromatography (GPC) similarly to the (meth)acrylic-polymer and was calculated in terms of polystyrene.

When the (meth)acrylic oligomer is used for the pressure-sensitive adhesive composition, the blending amount is not particularly limited, but is preferably 70 parts by weight or less, more preferably 1 to 70 parts by weight, still more preferably 2 to 50 parts by weight, and even still more preferably 3 to 40 parts by weight, with respect to 100 parts by weight of the (meth)acrylic polymer. By adjusting the blending amount of the (meth)acrylic oligomer within the above range, the (meth)acrylic oligomer is appropriately interposed between the (meth)acrylic polymers, so that the entanglement of the (meth)acrylic polymers is reduced and the pressure-sensitive adhesive layer is easily deformed with respect to minute strains. Thus, the strain applied to other layers can be reduced, and it is possible to suppress cracking of each layer and peeling between the pressure-sensitive adhesive layer and other layers. This is a preferable embodiment.

### <Crosslinking Agent>

The pressure-sensitive adhesive composition of the present invention may contain a crosslinking agent. An organic crosslinking agent or a polyfunctional metal chelate may be used as the crosslinking agent. Examples of the organic crosslinking agent include an isocyanate-based crosslinking agent, a peroxide-based crosslinking agent, an epoxy-based crosslinking agent, an imine-based crosslinking agent, and the like. The polyfunctional metal chelate may include those in which a polyvalent metal is covalently or coordinately bonded to an organic compound. Examples of the polyvalent metal atom include Al, Cr, Zr, Co, Cu, Fe, Ni, V, Zn, In, Ca, Mg, Mn, Y, Ce, Sr, Ba, Mo, La, Sn, Ti, and the like. Examples of the atom in the organic compound that is covalently or coordinately bonded include an oxygen atom and the like. Examples of the organic compound include alkyl esters, alcohol compounds, carboxylic acid compounds, ether compounds, ketone compounds, and the like. Among these, it is preferable to use an isocyanate-based crosslinking agent. Isocyanate-based crosslinking agents (especially trifunctional isocyanate-based crosslinking agents) are preferable in terms of durability, and a combination use of a peroxide-based crosslinking agent and an isocyanate-based crosslinking agent (particularly a bifunctional isocyanate-based crosslinking agent) is preferable from the viewpoint of bendability. Both the peroxide-based crosslinking agent and the bifunctional isocyanate-based crosslinking agent form a flexible two-dimensional crosslinking, whereas the trifunctional isocyanate-based crosslinking agent forms a stronger three-dimensional crosslinking. When bending, two-dimensional crosslinking, which is a more flexible crosslinking, is advantageous. However, since two-dimensional crosslinking alone is poor in durability, and peeling is likely to occur, hybrid crosslinking between two-dimensional crosslinking and three-dimensional crosslinking is favorable, so that a trifunctional isocyanate-based crosslinking agent is preferably used in combination with a peroxide-based crosslinking agent or a bifunctional isocyanate-based crosslinking agent. This is a preferable embodiment.

The amount of the crosslinking agent to be used is preferably 0.1 to 10 parts by weight, more preferably 0.2 to 8 parts by weight, and still more preferably 0.3 to 5 parts by weight, with respect to 100 parts by weight of the (meth)acrylic polymer. Within the above range, a preferred embodiment excellent in bending resistance is obtained.

In addition, when an isocyanate-based crosslinking agent is used alone, the amount is preferably 0.02 parts by weight or more, more preferably 0.09 parts by weight or more, still more preferably 0.5 parts by weight or more, with respect to 100 parts by weight of the (meth)acrylic polymer, and preferably 5 parts by weight or less, more preferably 3 parts by weight or less, still more preferably 1 part by weight or less. If the amount of such an isocyanate-based crosslinking agent is within the above range, the bending resistance and the end part quality due to the reduction in the amount of deviation of the pressure-sensitive adhesive layer will be excellent, and this is a preferable embodiment.

### <Other Additives>

Further, the pressure-sensitive adhesive composition of the present invention may contain any other known additives, including, for example, various silane coupling agents, polyether compounds of polyalkylene glycol (e.g. polypropylene glycol etc.), powder such as coloring agents and pigments, dyes, surfactants, plasticizers, tackifiers, surface lubricants, leveling agents, softeners, antioxidants, anti-ageing agents, light stabilizers, ultraviolet absorbers, polymerization inhibitors, antistatic agents (alkali metal salt which is an ionic compound, ionic liquid, or ionic solid), inorganic or organic fillers, metal powder, particle- or foil-shaped materials, and the like, and such additives can be appropriately added depending on the intended use. In addition, a redox system including a reducing agent to be added may also be used in the controllable range.

Although the preparation method of the pressure-sensitive adhesive composition is not specifically limited, a well-known method can be used. For example, a solvent-type acrylic pressure-sensitive adhesive composition is prepared by mixing (meth)acrylic polymer and optionally a component (for example, the (meth)acrylic oligomer, crosslinking agent, silane coupling agent, solvent, additive, etc.). In addition, as described above, the active energy ray-curable acrylic pressure-sensitive adhesive composition is prepared by mixing a monomer mixture or a partially polymerized product thereof, and components added as necessary (for example, the photopolymerization initiator, polyfunctional monomer, the (meth)acrylic oligomer, crosslinking agent, silane coupling agent, solvent, additive, etc.).

The pressure-sensitive adhesive composition preferably has a viscosity suitable for handling and coating. For this reason, it is preferable that the active energy ray-curable acrylic pressure-sensitive adhesive composition contains a partially polymerized product of a monomer mixture. The polymerization rate of the partially polymerized product is not particularly limited, but is preferably 5 to 20% by weight, more preferably 5 to 15% by weight.

Further, the polymerization rate of the partially polymerized product can be determined as follows.

A part of the partially polymerized product was sampled to prepare a sample. The sample is precisely weighed, and its weight is defined as “weight of partially polymerized product before drying”. Next, the sample is dried at 130° C. for 2 hours, and the dried sample is precisely weighed to obtain its weight, which is defined as “weight of partially polymerized product after drying”. Then, from the “weight of the partially polymerized product before drying” and the “weight of the partially polymerized product after drying”, the weight of the sample which is decreased by drying at 130° C. for 2 hours is defined as “weight reduction amount” (volatile content, unreacted monomer weight).

From the obtained “weight of partially polymerized product before drying” and “weight reduction amount”, the polymerization rate (% by weight) of the partially polymerized product of the monomer component is determined according to the following formula.

Polymerization rate (% by weight) of partially polymerized product of monomer component=[1−(weight reduction amount)/(weight of partially polymerized product before drying)]×100

### [Other Pressure-Sensitive Adhesive Layers]

Of the pressure-sensitive adhesive layer used in the laminate for a flexible image display device according to the present invention, a second pressure-sensitive adhesive layer may be arranged on the side opposite to the surface in contact with the polarizing membrane with respect to the retardation membrane (see FIG. 2).

Of the pressure-sensitive adhesive layer used in the laminate for a flexible image display device according to the present invention, a third pressure-sensitive adhesive layer can be arranged on the side opposite to the surface in contact with the second pressure-sensitive adhesive layer with respect to the transparent conductive layer constituting the touch sensor (see FIG. 2).

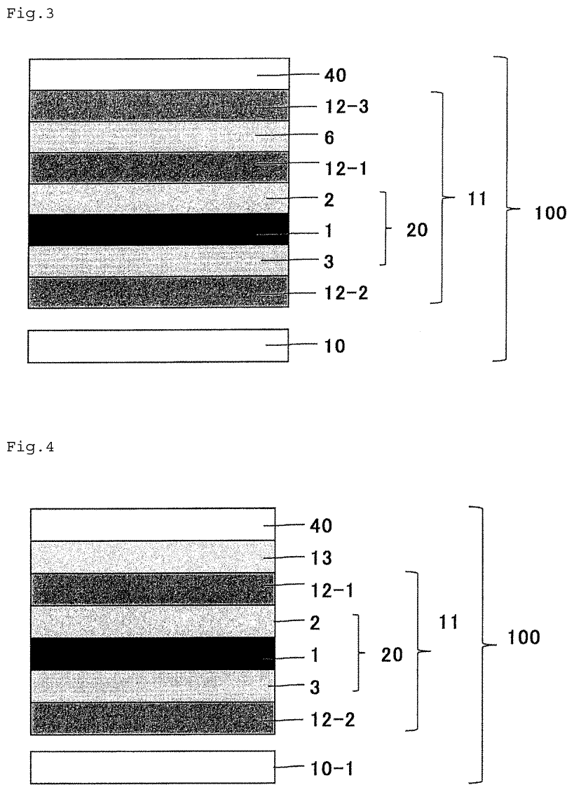

Of the pressure-sensitive adhesive layer used in the laminate for a flexible image display device according to the present invention, a third pressure-sensitive adhesive layer may be arranged on the side opposite to the surface in contact with the first pressure-sensitive adhesive layer with respect to the transparent conductive layer constituting the touch sensor (see FIG. 3).

When using the second pressure-sensitive adhesive layer and other pressure-sensitive adhesive layers (for example, the third pressure-sensitive adhesive layer) in addition to the first pressure-sensitive adhesive layer, these pressure-sensitive adhesive layers may have the same composition (same pressure-sensitive adhesive composition) and may have the same characteristics or may have different characteristics, and thus they are not particularly limited. From the viewpoints of workability, economic efficiency, and bendability, it is preferable that all the pressure-sensitive adhesive layers are those each having substantially the same composition and the same characteristics.

### <Formation of Pressure-Sensitive Adhesive Layer>

As the methods of forming the pressure-sensitive adhesive layer, for example, there are exemplified a method of forming a pressure-sensitive adhesive layer by applying the solvent-type pressure-sensitive adhesive composition to a separator or the like subjected to a release treatment and drying and removing the polymerization solvent or the like; a method of applying the solvent-type pressure-sensitive adhesive composition to a polarizing film, etc., drying and removing the polymerization solvent, etc., and forming a pressure-sensitive adhesive layer on the polarizing film, etc.; a method of applying an active energy ray-curable type pressure-sensitive adhesive composition to a separator or the like subjected to a release treatment and irradiating an active energy ray thereon to form a pressure-sensitive adhesive layer; and the like. In addition to the active energy ray irradiation, heat drying may be performed as necessary. In applying the pressure-sensitive adhesive composition, one or more solvents other than the polymerization solvent may be newly added as appropriate.

A silicone release liner is preferably used as the release-treated separator. When the pressure-sensitive adhesive composition of the present invention is applied to such a liner and dried to form a pressure-sensitive adhesive layer, any appropriate drying method may be suitably adopted depending on the purpose. A method of heating and drying the coating film is preferably used. When preparing an acrylic pressure-sensitive adhesive containing a (meth)acrylic polymer, the heating and drying temperature is, for example, preferably from 40° C. to 200° C., more preferably from 50° C. to 180° C., particularly preferably from 70° C. to 170° C. By setting the heating and drying temperature in the above range, a pressure-sensitive adhesive layer having good adhesive properties can be obtained.

Suitable heat drying time can be appropriately adopted. When preparing an acrylic pressure-sensitive adhesive containing a (meth)acrylic polymer, the heat drying time is, for example, preferably 5 seconds to 20 minutes, more preferably 5 seconds to 10 minutes, and particularly preferably 10 seconds to 5 minutes.

As a coating method of the pressure-sensitive adhesive composition, various methods may be used. Specific examples of such methods include a roll coating method, a kiss roll coating method, a gravure coating method, a reverse coating method, a roll brush coating method, a spray coating method, a dip roll coating method, a bar coating method, a knife coating method, an air knife coating method, a curtain coating method, a lip coating method, and an extrusion coating method with a die coater or the like.

The thickness of the pressure-sensitive adhesive layer used for the laminate for a flexible image display device according to the present invention is preferably 1 to 200 μm, more preferably 5 to 150 μm, still more preferably 10 to 100 μm. The pressure-sensitive adhesive layer may be a single layer or may have a laminated structure. The thickness within the above range is a preferred embodiment in terms of not inhibiting bending as well as in terms of adhesiveness (retention resistance).

The total thickness (total) of the pressure-sensitive adhesive layers used in the laminate for a flexible image display device according to the present invention is preferably 60 to 1000 μm, more preferably 120 to 660 μm, and still more preferably 150 to 500 μm. The pressure-sensitive adhesive layer may be a single layer or may have a plurality of layers. If the total thickness of the pressure-sensitive adhesive layer (the total of the thicknesses of all pressure-sensitive adhesive layers when a plurality of pressure-sensitive adhesive layers is present) is within the above range, a preferred embodiment is provided without hindering the bending and in terms of adhesiveness (retention resistance).

In the laminate for a flexible image display device according to the present invention, it is preferable that a storage elastic modulus G′ at 25° C. of the pressure-sensitive adhesive layer is 4×10⁴ to 8×10⁵ Pa. By keeping the storage elastic modulus G′ at 25° C. of the pressure-sensitive adhesive layer within the above range, the amount of deformation of the pressure-sensitive adhesive layer at the time of bending can be suppressed while maintaining the adhesiveness between the pressure-sensitive adhesive layer and each layer. When the storage elastic modulus G′ is less than 4×10⁴ Pa, the amount of deformation of the pressure-sensitive adhesive layer increases and the amount of deviation due to (based on) the pressure-sensitive adhesive layer increases, resulting in the reduction of end part quality. When the storage elastic modulus G′ exceeds 8×10⁵ Pa, the stress relaxation property of the pressure-sensitive adhesive layer and the adhesiveness between the pressure-sensitive adhesive layer and each layer are lowered, and the amount of deviation due to (based on) the pressure-sensitive adhesive layer becomes too small, so that the strain applied to each adjacent layer increases, each layer breaks and the pressure-sensitive adhesive layer peels off, or a lateral sliding occurs between the pressure-sensitive adhesive layer and the adjacent layer, which is not preferable. The storage elastic modulus G′ is preferably 6×10⁵ Pa or less, more preferably 4×10⁵ Pa or less. In addition, the storage elastic modulus G′ is preferably 8×10⁴ Pa or more, more preferably 1×10⁵ Pa or more.

The upper limit of the glass transition temperature (Tg) of the pressure-sensitive adhesive layer used in the laminate for a flexible image display device according to the present invention is preferably 0° C. or less, more preferably −20° C. or less, still more preferably −25° C. or less. If the Tg of the pressure-sensitive adhesive layer is within the above range, the pressure-sensitive adhesive layer is difficult to be hardened even when bent in a low temperature environment or in a high speed region where the bending speed exceeds 1 second/time, and has excellent stress relaxation properties. Thus, a flexible image display device that is excellent in stress relaxation and can be bent or folded can be realized.

The total light transmittance (according to JIS K7136) in the visible light wavelength region of the pressure-sensitive adhesive layer for a flexible image display device according to the present invention is preferably 85% or more, more preferably 90% or more.

### [Transparent Conductive Layer]

A member having a transparent conductive layer is not particularly limited and known materials can be used. Examples of such a member include a member having a transparent conductive layer on a transparent substrate such as a transparent film or the like and a member having a transparent conductive layer and a liquid crystal cell.

The transparent substrate may be of any type having transparency, and examples thereof include a substrate (for example, a sheet-like, film-like, or plate-like substrate) made of a resin film or the like. The thickness of the transparent substrate is not particularly limited, but is preferably about 10 to 200 μm, more preferably about 15 to 150 μm.

The material of the resin film is not particularly limited, and various plastic materials having transparency can be exemplified. Examples of such materials include polyester-based resins such as polyethylene terephthalate and polyethylene naphthalate, acetate-based resins, polyethersulfone-based resins, polycarbonate-based resins, polyamide-based resins, polyimide-based resins, polyolefin-based resins, (meth)acrylic resins, polyvinyl chloride-based resins, polyvinylidene chloride-based resins, polystyrene-based resins, polyvinyl alcohol-based resins, polyarylate-based resins, and polyphenylene sulfide-based resins. Among them, polyester-based resins, polyimide-based resins, and polyethersulfone-based resins are particularly preferred.

The surface of the transparent substrate may be previously subjected to sputtering, corona discharge treatment, flame treatment, ultraviolet irradiation, electron beam irradiation, chemical treatment, etching treatment such as oxidation, or undercoating treatment so that the transparent substrate can have improved adhesiveness to the transparent conductive layer formed thereon. Before the transparent conductive layer is formed, if necessary, the transparent substrate may be subjected to solvent washing or ultrasonic washing for removal of dust and cleaning.

Examples of the material used to form the transparent conductive layer include, but not limited to, at least a metal or an oxide of a metal selected from the group consisting of indium, tin, zinc, gallium, antimony, titanium, silicon, zirconium, magnesium, aluminum, gold, silver, copper, palladium, tungsten, and molybdenum, and an organic conductive polymer such as polythiophene. If necessary, the metal oxide may further contain a metal atom shown in the above group. For example, tin oxide-doped indium oxide (ITO) and antimony-doped tin oxide are preferably used, and in particular, ITO is preferably used. ITO preferably contains 80 to 99% by weight of indium oxide and 1 to 20% by weight of tin oxide.

The ITO may be crystalline or amorphous. The crystalline ITO can be obtained by high-temperature sputtering or further heating an amorphous ITO.

The thickness of the transparent conductive layer of the present invention is preferably 0.005 to 10 μm, more preferably 0.01 to 3 μm, still more preferably 0.01 to 1 μm. When the thickness of the transparent conductive layer is less than 0.005 μm, the transparent conductive layer tends to be more variable in electric resistance. On the other hand, the transparent conductive layer with a thickness of more than 10 μm may be produced with a lower productivity at higher cost and tend to have a lower level of optical properties.

The total light transmittance of the transparent conductive layer of the present invention is preferably 80% or more, more preferably 85% or more, still more preferably 90% or more.

The density of the transparent conductive layer of the present invention is preferably 1.0 to 10.5 g/cm³, more preferably 1.3 to 3.0 g/cm³.

The surface resistance value of the transparent conductive layer of the present invention is preferably 0.1 to 1,000Ω/□, more preferably 0.5 to 500Ω/□, still more preferably 1 to 250Ω/□.

The method for forming the transparent conductive layer is not particularly limited, and conventionally known methods can be adopted. Specifically, for example, a vacuum deposition method, a sputtering method, and an ion plating method can be exemplified. In addition, an appropriate method can be adopted according to the required film thickness.

In addition, if necessary, an undercoat layer, an oligomer prevention layer, and the like can be provided between the transparent conductive layer and the transparent substrate.

The transparent conductive layer forms a touch sensor and is required to be configured to be foldable.

In the laminate for a flexible image display device according to the present invention, the transparent conductive layer constituting the touch sensor can be arranged on the side opposite to the surface in contact with the retardation membrane with respect to the second pressure-sensitive adhesive layer (see FIG. 2).

In the laminate for a flexible image display device according to the present invention, the transparent conductive layer constituting the touch sensor can be arranged on the side opposite to the surface in contact with the protective membrane with respect to the first pressure-sensitive adhesive layer (see FIG. 3).

Further, in the laminate for a flexible image display device according to the present invention, the transparent conductive layer constituting the touch sensor can be arranged between the protective membrane and a window film (OCA) (see FIG. 3).

The transparent conductive layer can be suitably applied to a liquid crystal display device incorporating a touch sensor such as an in-cell type or an on-cell type as used in a flexible image display device, and in particular, a touch sensor may be built in (or incorporated in) an organic EL display panel.

### [Conductive Layer (Antistatic Layer)]

Further, the laminate for a flexible image display device according to the present invention may have a layer having conductivity (a conductive layer, an antistatic layer). Since the laminate for a flexible image display device has a bending function and has a very thin thickness structure, such a laminate is highly reactive to weak static electricity generated in a manufacturing process or the like and is easily damaged, but by providing a conductive layer in the laminate, the load due to static electricity in the manufacturing process and the like is largely reduced, which is a preferable embodiment.

In addition, one of the great features is that the flexible image display device including the laminate has a bending function. When the flexible image display device is continuously bent, static electricity may be generated due to contraction between the layers (film, substrate) of the bent portion. Therefore, when conductivity is imparted to the laminate, generated static electricity can be promptly removed, and damage caused by static electricity of the image display device can be reduced, which is a preferable embodiment.

Further, the conductive layer may be an undercoat layer having a conductive function, a pressure-sensitive adhesive containing a conductive component, or a surface treatment layer containing a conductive component. For example, a method of forming a conductive layer between a polarizing film and a pressure-sensitive adhesive layer by using an antistatic composition containing a binder and a conductive polymer such as polythiophene can be employed. Further, a pressure-sensitive adhesive containing an ionic compound which is an antistatic agent can also be used. The conductive layer preferably has one or more layers and may contain two or more layers.

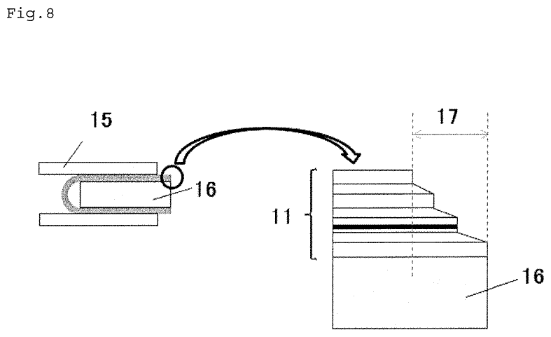

The laminate for a flexible image display device according to the present invention is a laminate for a flexible image display device, which includes a pressure-sensitive adhesive layer and an optical film including at least a polarizing membrane and is characterized in that the amount of deviation based on the pressure-sensitive adhesive layer in an end part of the laminate is 100 to 600 μm when the laminate is bent with a bending radius of 3 mm, preferably 150 to 580 μm, more preferably 200 to 550 μm, still more preferably 250 to 450 μm, and particularly preferably 250 to 350 μm. When the amount of deviation is within the above range, it is possible to suppress adhesive stain and stickiness in the end part of the laminate due to the pressure-sensitive adhesive layer constituting the laminate for a flexible image display device, so that the end quality is excellent, and the bending resistance and adhesiveness can be maintained, which is a preferred embodiment. In addition, when the amount of deviation is less than 100 μm, strain of each layer constituting the laminate cannot be alleviated and lateral sliding or peeling between layers tends to occur, which is not preferable. In general, it is considered that the amount of deviation caused by the pressure-sensitive adhesive layer should be small, but if the amount of deviation is too small, it becomes impossible to alleviate the strain between the respective layers. Thus, by adjusting the amount of deviation within the above range, it is possible to alleviate the strain as well as suppress the peeling, which is a preferable embodiment. When the amount of deviation due to the pressure-sensitive adhesive layer is within the above range, it is possible to obtain a laminate for a flexible image display device, excellent in bending resistance and adhesiveness without being peeled off or broken in each layer even with repeated bending. This is a preferable embodiment (see FIG. 8).

In addition, the amount of deviation (difference) based on the pressure-sensitive adhesive layer in the end part of the laminate refers to a total amount of deviation due to all pressure-sensitive adhesive layers when there is a plurality of pressure-sensitive adhesive layers. For example, in the case where in addition to the optical film, a plurality of pressure-sensitive adhesive layers and other layers (for example, a transparent conductive layer, a retardation layer, a protective membrane, etc.) are provided in the laminate for a flexible image display device, the amount of deviation based on the pressure-sensitive adhesive layer in the end part of the laminate refers to a total amount of deviation due to the plurality of pressure-sensitive adhesive layers. Moreover, in the case of a flexible image display device in which the laminate for a flexible image display device is contained, such amount of deviation may refer to a total amount of deviation due to (a plurality of) pressure-sensitive adhesive layer(s) in a state further including an organic EL display panel, a touch panel, a decorative printing film, and the like.

The total thickness of the laminate for a flexible image display device according to the present invention is preferably 1200 μm or less, more preferably 900 μm or less, and still more preferably 700 μm or less. Moreover, the total thickness of the laminate is preferably 100 μm or more, and more preferably 150 μm or more. When the total thickness is more than 1200 μm, the difference in strains applied to the outermost layer and the innermost layer constituting the laminate in the bent portion of the laminate increases, so that cracking and peeling are likely to occur during bending. Further, when the total thickness is thicker than 1200 μm, the amount of strain of the pressure-sensitive adhesive layer also increases, so that the amount of deviation between the outermost layer and the innermost layer constituting the laminate due to a plurality of pressure-sensitive adhesive layers increases, resulting in quality deterioration in the end part, which is not preferable.

### [Flexible Image Display Device]

The flexible image display device of the present invention includes the laminate for a flexible image display device and an organic EL display panel configured to be foldable, wherein the laminate for a flexible image display device is arranged on the viewing side with respect to the organic EL display panel. A window may be optionally arranged on the viewing side with respect to the laminate for a flexible image display device (see FIGS. 2 to 4).

FIG. 2 is a cross-sectional view showing one embodiment of a flexible image display device according to the present invention. This flexible image display device 100 includes a laminate 11 for a flexible image display device and an organic EL display panel 10 configured to be foldable. The laminate 11 for a flexible image display device is arranged on the viewing side with respect to the organic EL display panel 10, and the flexible image display device 100 is configured to be foldable. Further, although optional, a transparent window 40 can be arranged on the viewing side with an interposed first pressure-sensitive adhesive layer 12-1 with respect to the laminate 11 for a flexible image display device.

The laminate 11 for a flexible image display device includes an optical laminate 20 and a pressure-sensitive adhesive layer forming a second pressure-sensitive adhesive layer 12-2 and a third pressure-sensitive adhesive layer 12-3.

The optical laminate 20 includes a polarizing membrane 1, a protective membrane 2 made of a transparent resin material, and a retardation membrane 3. The protective membrane 2 made of a transparent resin material is bonded to a first surface on the viewing side of the polarizing membrane 1. The retardation membrane 3 is bonded to a second surface different from the first surface of the polarizing membrane 1. For example, the polarizing membrane 1 and the retardation membrane 3 generate circularly polarized light in order to prevent incident light inside from the viewing side of the polarizing membrane 1 from being internally reflected and emitted to the viewing side, or to compensate a viewing angle.

In the present embodiment, a protective membrane is provided on one side only, whereas a protective membrane is conventionally provided on both sides of a polarizing membrane, and the thickness of the optical laminate 20 may be reduced by using a polarizing membrane itself having a very thin thickness (20 μm or less) as compared with a polarizing membrane used in a conventional organic EL display device. In addition, since the polarizing membrane 1 is much thinner than the polarizing membrane used in the conventional organic EL display device, stress due to expansion and contraction occurring under temperature or humidity conditions becomes extremely smaller. Therefore, the possibility that the stress caused by the shrinkage of the polarizing membrane causes deformation such as warping in the adjacent organic EL display panel 10 is greatly reduced, and deterioration of the display quality due to deformation as well as breakage of the panel sealing material can be greatly suppressed. In addition, by using a thin polarizing membrane, bending is not hindered, which is a preferable embodiment.

When the optical laminate 20 is folded with the protective membrane 2 side facing inside, the thickness (for example, 92 μm or less) of the optical laminate 20 is reduced, and the first pressure-sensitive adhesive layer 12-1 as described above is arranged on the side opposite to the retardation membrane 3 with respect to the protective membrane 2. In the laminate 11 for a flexible image display device including such an optical laminate 20, by adjusting the amount of deviation (difference) in the end part between the outermost layer and the innermost layer constituting the laminate for a flexible image display device due to the pressure-sensitive adhesive layer, that is, by adjusting the amount (total) of deviation of the pressure-sensitive adhesive layer to a specific range, folding can be made without causing cracking or peeling of each layer constituting the optical laminate 20 and the laminate 11 for a flexible image display device including the optical laminate, and the end part quality can also be maintained. Further, the flexible image display device including the laminate 11 for a flexible image display device can be folded without causing cracking or peeling of each layer, and the end part quality can be also maintained. Moreover, the pressure-sensitive adhesive layer which set the range of the appropriate storage elastic modulus according to the environmental temperature where the flexible image display device including the laminate 11 for a flexible image display device is used can be used. For example, when the assumed use environment temperature is −20° C. to +85° C., the first pressure-sensitive adhesive layer can be used so that the storage elastic modulus at 25° C. falls within an appropriate numerical range.

Optionally, a foldable transparent conductive layer 6 forming a touch sensor may further be arranged on the side opposite to the protective membrane 2 with respect to the retardation membrane 3. The transparent conductive layer 6 is configured to be directly bonded to the retardation membrane 3 by a manufacturing method as disclosed in, for example, JP-A-2014-219667, whereby the thickness of the optical laminate 20 is reduced and the stress applied to the optical laminate 20 when the optical laminate 20 is folded can be further reduced.

Optionally, a pressure-sensitive adhesive layer forming a third pressure-sensitive adhesive layer 12-3 can be further arranged on the side opposite to the retardation membrane 3 with respect to the transparent conductive layer 6. In the present embodiment, the second pressure-sensitive adhesive layer 12-2 is directly bonded to the transparent conductive layer 6. By providing the second pressure-sensitive adhesive layer 12-2, it is possible to further reduce the stress applied to the optical laminate 20 when folded.

The flexible image display device shown in FIG. 3 is substantially the same as that shown in FIG. 2. In the flexible image display device of FIG. 2, a foldable transparent conductive layer 6 forming a touch sensor is arranged on the side opposite to the protective membrane 2 with respect to the retardation membrane 3, whereas in the flexible image display device of FIG. 3, a foldable transparent conductive layer 6 forming a touch sensor is differently arranged on the side opposite to the protective membrane 2 with respect to the first pressure-sensitive adhesive layer 12-1. Further, there is a different point in that in the flexible image display device of FIG. 2, the third pressure-sensitive adhesive layer 12-3 is arranged on the side opposite to the retardation membrane 3 with respect to the transparent conductive layer 2, whereas in the flexible image display device of FIG. 3, the second pressure-sensitive adhesive layer 12-2 is arranged on the side opposite to the protective membrane 2 with respect to the retardation membrane 3.

In addition, although optional, the third pressure-sensitive adhesive layer 12-3 can be arranged when the window 40 is arranged on the viewing side with respect to the laminate 11 for a flexible image display device.

The flexible image display device of the present invention can be suitably used as an image display device such as a flexible liquid crystal display device, an organic EL (electroluminescence) display device, and an electronic paper. Further, such a flexible image display device can be used irrespective of a touch panel or the like such as a resistive film type or a capacitive type.

In addition, the flexible image display device of the present invention may also be used as an in-cell type flexible image display device in which the transparent conductive layer 6 forming a touch sensor is incorporated in an organic EL display panel 10-1, as shown in FIG. 4.

### EXAMPLES

Several examples relating to the present invention will be described below, but the present invention is not intended to be limited to such specific examples. In addition, the numerical values in tables are blending amounts (addition amounts) and showed solid contents or solid fractions (weight basis). The contents of the formulation and the evaluation results are shown in Tables 1 to 5.

### Example 1

### [Polarizing Membrane]

An amorphous polyethylene terephthalate (hereinafter referred to as “PET”) (IPA-copolymerized PET) film (thickness: 100 μm) with 7 mol % of isophthalic acid unit was used as a thermoplastic resin substrate, and a surface of the film was subjected to a corona treatment (58W/m²/min). On the other hand, a PVA (polymerization degree: 4200, saponification degree: 99.2%) added with 1% by weight of acetoacetyl-modified PVA (trade name: Gohsefimer 2200 (average polymerization degree: 1200, saponification degree: 98.5 mol %, acetoacetylation degree: 5 mol %, manufactured by Nippon Synthetic Chemical Industry Co., Ltd.) was used to preliminarily prepare a coating solution of PVA aqueous solution with 5.5% by weight of a PVA-based resin. Then, the coating solution was applied onto a substrate to allow a film thickness after drying to become 12 μm and subjected to hot-air drying under an atmosphere at 60° C. for 10 minutes to prepare a laminate in which a layer of the PVA-based resin is provided on the substrate.

Then, this laminate was first subjected to free-end stretching in air (auxiliary in-air stretching) at 130° C. at a stretching ratio of 1.8 times to form a stretched laminate. Then, the stretched laminate was immersed in a boric acid insolubilizing aqueous solution having a temperature of 30° C. for 30 seconds to perform a step of insolubilizing a PVA layer in which the PVA molecules contained in the stretched laminate are aligned. The boric acid insolubilizing aqueous solution in this step was prepared to allow a boric acid to be contained in an amount of 3 parts by weight with respect to 100 parts by weight of water. The stretched laminate was subjected to dyeing to form a dyed laminate. The dyed laminate was prepared by immersing the stretched laminate in a dyeing solution containing iodine and potassium iodide and having a temperature of 30° C. for an arbitrary time, in such a manner that a single layer transmittance of the PVA layer making up a polarizing membrane to be finally obtained falls with the range of 40 to 44%, thereby causing the PVA layer included in the stretched laminate to be dyed with iodine. In this step, the dyeing solution was prepared using water as a solvent to allow an iodine concentration and a potassium iodide concentration to fall within the range of 0.1 to 0.4% by weight and 0.7 to 2.8% by weight, respectively. A concentration ratio of iodine to potassium iodide was 1:7. Then, a step of crosslinking PVA molecules in the PVA layer on which iodine was adsorbed was performed by immersing the dyed laminate in a boric acid crosslinking aqueous solution at 30° C. for 60 seconds. The boric acid crosslinking aqueous solution in this step was set to contain boric acid in an amount of 3 parts by weight with respect to 100 parts by weight of water and contain potassium iodide in an amount of 3 parts by weight with respect to 100 parts by weight of water.

Further, an obtained dyed laminate was stretched in an aqueous boric acid solution (stretching in an aqueous boric acid solution) at a stretching temperature of 70° C. at a stretching ratio of 3.05 times in the same direction as that during the previous in-air stretching to obtain an optical film laminate stretched at a final stretching ratio of 5.50 times. The optical film laminate was taken out of the aqueous boric acid solution, and a boric acid attached to a surface of the PVA layer was washed with an aqueous solution containing 4 parts by weight of potassium iodide with respect to 100 pars by weight of water. The washed optical film laminate was dried through a drying step using hot air at 60° C. The polarizing membrane included in the obtained optical film laminate had a thickness of 5 μm.

### [Protective Membrane]

A protective membrane obtained by extruding a methacrylic resin pellet having a glutarimide ring unit to form a film shape and then stretching the membrane was used. This protective membrane had a thickness of 20 μm and was an acrylic film having a moisture permeability of 160 g/m².

Next, the polarizing membrane and the protective membrane were bonded using an adhesive shown below to obtain a polarizing film.

As the adhesive (active energy ray-curable type adhesive), each component was mixed according to the formulation table shown in Table 1 and stirred at 50° C. for 1 hour to prepare an adhesive (active energy ray-curable type adhesive A). Numerical values in the table indicate a weight % when the total amount of the composition is taken as 100% by weight. Each component used is as follows.

HEAA: Hydroxyethylacrylamide

M-220: ARONIX M-220, tripropylene glycol diacrylate) manufactured by Toagosei Co., Ltd.

ACMO: Acryloyl morpholine

AAEM: 2-Acetoacetoxyethyl methacrylate, manufactured by The Nippon Synthetic Chemical Industry Co., Ltd.

UP-1190: ARUFON UP-1190, manufactured by Toagosei Co., Ltd.

IRG 907: IRGACURE 907, 2-methyl-1-(4-methylthiophenyl)-2-morpholinopropan-1-one, manufactured by BASF

DETX-S: KAYACURE DETX-S, diethylthioxanthone, manufactured by Nippon Kayaku Co., Ltd.

TABLE 1

| | Composition of |
|---|---|
| (% by weight) | adhesive |
| HEAA | 11.4 |
| M-220 | 57.1 |
| ACMO | 11.4 |
| AAEM | 4.6 |
| UP-1190 | 11.4 |
| IRG907 | 2.8 |
| DETX-S | 1.3 |

In Examples and Comparative Examples using the adhesive, after the protective membrane and the polarizing membrane were laminated with the interposed adhesive, the adhesive was cured by irradiation with ultraviolet rays to form an adhesive layer. For irradiation with ultraviolet rays, a gallium-encapsulated metal halide lamp (trade name “Light HAMMER 10” manufactured by Fusion UV Systems, Inc., bulb: V bulb, peak illuminance: 1,600 mW/cm², integrated irradiation amount: 1,000/mJ/cm² (wavelength 380 to 440 nm)) was used.

### [Retardation Membrane]

The retardation membrane (a quarter wavelength retardation plate) of this Example was a retardation membrane composed of two layers of a retardation layer for a quarter wavelength plate and a retardation layer for a half wavelength plate, in which a liquid crystal material is aligned and fixed. Specifically, such a retardation membrane was manufactured as follows.

### (Liquid Crystal Material)

A polymerizable liquid crystal material (trade name: Paliocolor LC242, manufactured by BASF) showing a nematic liquid crystal phase was used as a material for forming a retardation layer for a half wavelength plate and a retardation layer for a quarter wavelength plate. A photopolymerization initiator (trade name IRGACURE 907, manufactured by BASF) for the polymerizable liquid crystal material was dissolved in toluene. Further, for the purpose of improving the coating property, a MEGAFACE series manufactured by DIC Corporation was added in an amount of about 0.1 to 0.5% according to the liquid crystal thickness to prepare a liquid crystal coating solution. The liquid crystal coating solution was applied on an alignment substrate with a bar coater, dried by heating at 90° C. for 2 minutes, and subjected to alignment fixation by ultraviolet curing under a nitrogen atmosphere. As the substrate, for example, one capable of transferring the liquid crystal coating layer later, such as PET, was used. Further, for the purpose of improving coatability, a fluorine-based polymer which is a MEGAFACE series manufactured by DIC Corporation was added in an amount of about 0.1% to 0.5% depending on the thickness of the liquid crystal layer, and MIBK (methyl isobutyl ketone), cyclohexanone, or a mixed solvent of MIBK and cyclohexanone was used to dissolve the polymer to a solid content concentration of 25%, thereby to prepare a coating solution. This coating solution was applied on a substrate with a wire bar, dried at 65° C. for 3 minutes, and subjected to alignment fixation by ultraviolet curing under a nitrogen atmosphere to perform the preparation. As the substrate, for example, one capable of transferring the liquid crystal coating layer later, such as PET, was used.

### (Manufacturing Process)

The manufacturing process of the present Example will be described with reference to FIG. 7. The numbers in FIG. 7 are different from the numbers in other drawings. In this manufacturing process 20, a substrate 14 was provided by a roll, and this substrate 14 was supplied from a supply reel 21. In the manufacturing process 20, a coating solution of an ultraviolet curable resin 10 was applied to the substrate 14 by a die 22. In the manufacturing process 20, a roll plate 30 was a cylindrical shaping mold in which a concavo-convex shape relating to an alignment membrane for a quarter wavelength plate of a quarter wavelength retardation plate was formed on the peripheral side surface. In the manufacturing process 20, the substrate 14 coated with the ultraviolet curable resin is pressed against the circumferential side surface of the roll plate 30 by a pressure roller 24, and the ultraviolet curable resin was irradiated with ultraviolet light by an ultraviolet irradiation device 25 composed of a high-pressure mercury lamp and then cured. As a result, in the manufacturing process 20, the concavo-convex shape formed on the peripheral side surface of the roll plate 30 was transferred to the substrate 14 so as to be at 75° with respect to the MD direction. Thereafter, the substrate 14 integrally with the cured ultraviolet curable resin 10 was peeled from the roll plate 30 by a peeling roller 26, and the liquid crystal material was applied thereon by a die 29. After that, the liquid crystal material was cured by irradiation with ultraviolet rays by an ultraviolet irradiation device 27, whereby a configuration relating to the retardation layer for a quarter wavelength plate was prepared.

Subsequently, in this process 20, the substrate 14 is conveyed to a die 32 by a conveying roller 31, and the coating solution of an ultraviolet curable resin 12 is applied onto the retardation layer for a quarter wavelength plate of the substrate 14 by the die 32. In this manufacturing process 20, a roll plate 40 was a cylindrical shaping mold in which a concavo-convex shape relating to the alignment membrane for a half wavelength plate of the quarter wavelength retardation plate was formed on the circumferential side surface. In the manufacturing process 20, the substrate 14 coated with the ultraviolet curing resin was pressed against the peripheral side surface of the roll plate 40 by a pressure roller 34, and the ultraviolet curable resin was irradiated with ultraviolet rays by an ultraviolet irradiation device 35 composed of a high-pressure mercury lamp, and then cured. As a result, in the manufacturing process 20, the concavo-convex shape formed on the circumferential side surface of the roll plate 40 was transferred onto the substrate 14 so as to be at 15° with respect to the MD direction. Thereafter, the substrate 14 integrally with the cured ultraviolet curable resin 12 was peeled from the roll plate 40 by a peeling roller 36, and the liquid crystal material was applied thereon by a die 39. After that, the liquid crystal material was cured by irradiation with ultraviolet rays by an ultraviolet irradiation device 37, whereby a configuration relating to the retardation layer for a half wavelength plate was obtained. Thus, a retardation membrane having a thickness of 7 μm and composed of two layers of a retardation layer for a quarter wavelength plate and a retardation layer for a half wavelength plate was obtained.

### [Optical Film (Optical Laminate)]

The retardation membrane obtained as described above and the polarizing film obtained as described above were continuously laminated by the roll-to-roll method using the adhesive to prepare a laminated film (optical laminate) so that an axis angle became 45° between the slow axis and the absorption axis.

### [Second Pressure-Sensitive Adhesive Layer]

### <Preparation of (Meth)Acrylic Polymer A2>

A monomer mixture containing 94.9 parts by weight of butyl acrylate (BA), 0.1 parts by weight of 2-hydroxyethyl acrylate (HEA), and 5 parts by weight of acrylic acid (AA) was charged into a four-necked flask equipped with a stirring blade, a thermometer, a nitrogen gas inlet tube and a condenser.

Further, 0.3 parts by weight dibenzoyl peroxide (hyper BMT40 (SV), manufactured by NOF Corporation) as a polymerization initiator were added together with ethyl acetate to 100 parts by weight (solid content) of the monomer mixture, and nitrogen gas was introduced thereto with gentle stirring. After purging with nitrogen, polymerization reaction was carried out for 7 hours while maintaining the liquid temperature in the flask at around 55° C. Thereafter, ethyl acetate was added to the obtained reaction solution to adjust the solid content to a concentration of 30%, thereby to prepare a (meth)acrylic polymer A2 solution having a weight average molecular weight of 2.2 million.

### <Preparation of Acrylic Pressure-Sensitive Adhesive Composition (P1)>

An acrylic pressure-sensitive adhesive composition (P1) was prepared by blending 0.6 parts by weight of an isocyanate-based crosslinking agent (trade name: Coronate L, trimethylolpropane tolylene diisocyanate, manufactured by Nippon Polyurethane Industry Co., Ltd.) and 0.08 parts by weight of a silane coupling agent (trade name: KBM 403, manufactured by Shin-Etsu Chemical Co., Ltd.) with 100 parts by weight of the solid content of the obtained (meth)acrylic polymer A2 solution.

### <Preparation of Pressure-Sensitive Adhesive Layer Attached Optical Laminate>

The acrylic pressure-sensitive adhesive composition (P1) was uniformly applied to the surface of a polyethylene terephthalate film (separator) having a thickness of 38 μm treated with a silicone-based releasing agent, using a fountain coater, and dried at 155° C. in an air circulation type thermostatic oven for 2 minutes to form a second pressure-sensitive adhesive layer having a thickness of 70 μm on the surface of the substrate.

Next, a separator having the second pressure-sensitive adhesive layer formed thereon was transferred to the protective membrane side (corona-treated) of the obtained optical laminate to prepare a pressure-sensitive adhesive layer attached optical laminate.

### [First Pressure-Sensitive Adhesive Layer]

In the same manner as in the formation of the second pressure-sensitive adhesive layer, a first pressure-sensitive adhesive layer having a thickness of 50 μm was formed on the basis of the contents of the formulations in Tables 2 and 3, and a separator having the first pressure-sensitive adhesive layer formed thereon was transferred to the surface (corona-treated) of a polyimide film (PI film, KAPTON 300V, substrate, manufactured by Du Pont-Toray Co., Ltd.) having a thickness of 75 μm to form a pressure-sensitive adhesive layer attached PI film.

### [Third Pressure-Sensitive Adhesive Layer]

In the same manner as in the formation of the second pressure-sensitive adhesive layer, a third pressure-sensitive adhesive layer having a thickness of 50 μm was formed on the basis of the contents of the formulations in Tables 2 and 3, and a separator having the third pressure-sensitive adhesive layer formed thereon was transferred to the surface (corona-treated) of a PET film having a thickness of 125 μm (transparent substrate, trade name: DIAFOIL, manufactured by Mitsubishi Plastics, Inc.) to form a pressure-sensitive adhesive layer attached PET film.

### <Laminate for Flexible Image Display Device>

As shown in FIG. 6, with respect to the first to third pressure-sensitive adhesive layers (together with each transparent substrate) obtained as described above, the second pressure-sensitive adhesive layer 12-2 was bonded to a PET film which will be a transparent substrate 8-1 having a thickness of 25 μm, the third pressure-sensitive adhesive layer 12-3 was bonded to the retardation membrane 3, and further, the first pressure-sensitive adhesive layer 12-1 was bonded to the transparent substrate 8-1 (PET film) to which the second pressure-sensitive adhesive layer 12-2 was attached, thereby to produce the laminate 11 for a flexible image display device used in Examples.

<Preparation of Acrylic Oligomer (Oligomer B1)>

A four-necked flask equipped with a stirring blade, a thermometer, a nitrogen gas inlet tube, and a condenser was charged with 95 parts by weight of butyl acrylate (BA), 2 parts by weight of acrylic acid (AA), 3 parts by weight of methyl acrylate (MA), 0.1 parts by weight of 2,2′-azobisisobutyro-nitrile (AIBN) as a polymerization initiator, and 140 parts by weight of toluene, and nitrogen gas was introduced into the flask with gentle stirring to thoroughly purge the inside thereof with nitrogen. While keeping the liquid temperature in the flask at about 70° C., the polymerization reaction was carried out for 8 hours to prepare an acrylic oligomer (oligomer B1) solution. The oligomer B1 had a weight average molecular weight of 4,500.

### Examples 2 to 4 and Comparative Examples 1 to 2

In the preparation of the polymer ((meth)acrylic polymer), the acrylic oligomer, the pressure-sensitive adhesive composition, and the pressure-sensitive adhesive layer to be used, a laminate for a flexible image display device was produced in the same manner as in Example 1 with changes made as shown in Tables 2 to 4 other than those specifically described.

Further, each thickness of all layers including the pressure-sensitive adhesive layer used in Examples and Comparative Examples is the same as that used in Example 1.

Abbreviations in Table 2 and Table 3 are as follows.

BA: n-Butyl acrylate

AA: Acrylic acid

HBA: 4-Hydroxybutyl acrylate

HEA: 2-Hydroxyethyl acrylate

MA: Methyl acrylate

D110N: Trimethylolpropane/xylylene diisocyanate adduct (product name: Takenate D110N, manufactured by Mitsui Chemicals, Inc.)

C/L: Trimethylolpropane/tolylene diisocyanate (trade name: Coronate L, manufactured by Nippon Polyurethane Industry Co., Ltd.)

Peroxide: Benzoyl peroxide (trade name: Nyper BMT, manufactured by NOF Corporation)

### [Evaluation]

### <Measurement of Weight Average Molecular Weight (Mw) of (Meth)Acrylic Polymer and Acrylic Oligomer>

The weight average molecular weight (Mw) of each of the obtained (meth)acrylic polymer and acrylic oligomer was measured by GPC (gel permeation chromatography).
Analyzer: HLC-8120 GPC, manufactured by Tosoh Corporation
Column: G7000H_{XL}+GMH_{XL}+GMH_{XL}, manufactured by Tosoh Corporation
Column size: each 7.8 mmφ×30 cm, 90 cm in total
Column temperature: 40° C.
Flow rate: 0.8 ml/min
Injection volume: 100 μl
Eluent: Tetrahydrofuran
Detector: Differential refractometer (RI)
Standard sample: Polystyrene

### <Measurement of Storage Elastic Modulus G′ of Pressure-Sensitive Adhesive Layer>

A separator was peeled from the pressure-sensitive adhesive layer of each of Examples and Comparative Examples, and a plurality of pressure-sensitive adhesive layers was laminated to prepare a test sample having a thickness of about 2 mm. The test sample was punched into a disk shape having a diameter of 7.9 mm, sandwiched between parallel plates, and dynamic viscoelasticity measurement was performed using “Advanced Rheometric Expansion System (ARES)” manufactured by Rheometric Scientific, Inc. under the following conditions. From the measurement results, the storage elastic modulus G′ at 25° C. of the pressure-sensitive adhesive layer was read.

### (Measurement Conditions)

Deformation mode: twisting

Measurement temperature: −40° C. to 150° C.

Temperature rising rate: 5° C./min

### <Measurement of Thickness>

The thickness of the polarizing membrane, the retardation membrane, the protective membrane, the optical laminate, the pressure-sensitive adhesive layer, and the like were measured using a dial gauge (manufactured by Mitutoyo Corporation).

### <Folding Resistance (Continuous Bending) Test>

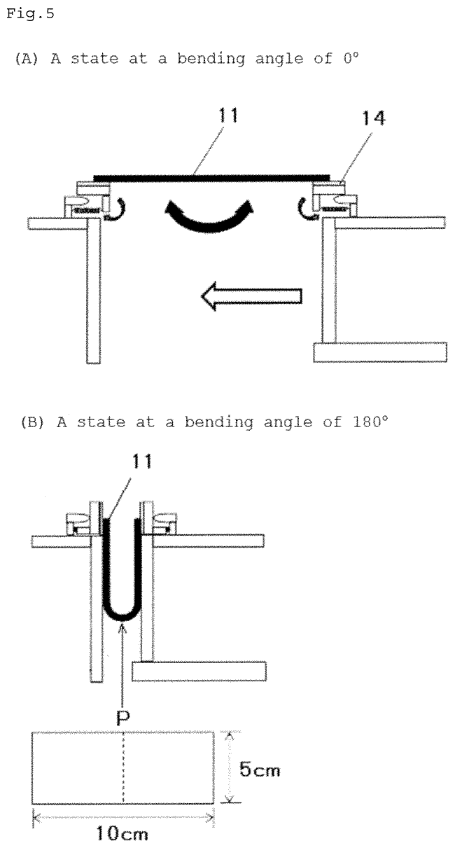

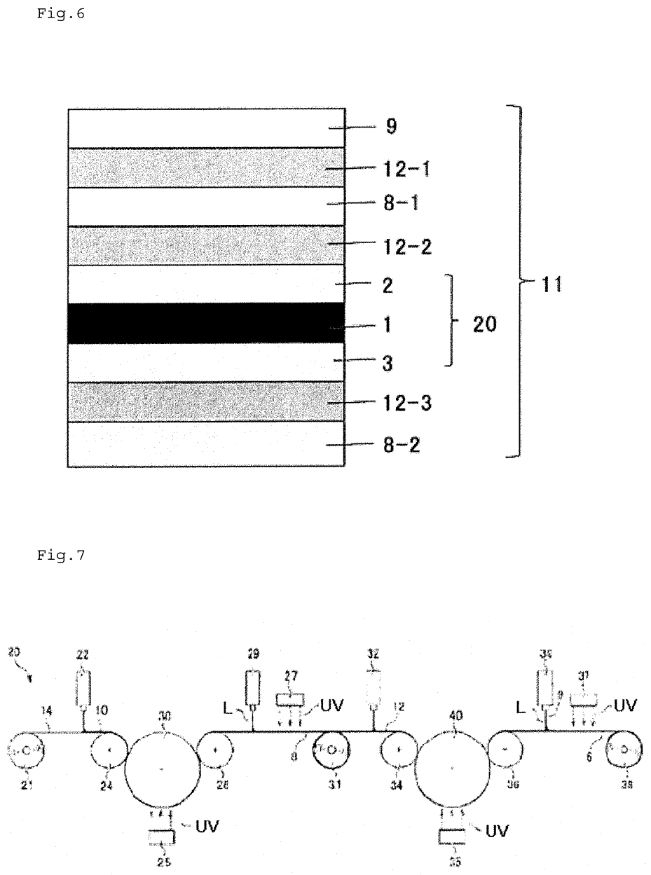

FIGS. 5(A) and 5(B) show schematic diagrams of a bending test based on a U extending testing machine (YUASA SYSTEM CO., LTD.).

The above machine has a mechanism that repeats 180° bending into a U-shape with non-burden on a planar workpiece in a thermostatic chamber, and the folding radius can be changed by adjusting the distance between the surfaces folded into the U-shape.

In the test, a laminate of 2.5 cm×10 cm obtained in each of Examples and Comparative Examples for a flexible image display device was set in a test machine in such a manner that the laminate could be folded in the long side direction, and evaluation was performed under the condition of 25° C.×50% RH, a bending angle of 180°, a bending radius of 3 mm, and a bending speed of 1 second/time.

As the measurement (evaluation) sample, a configuration shown in FIG. 6 was adopted. Evaluation on the bending resistance was performed by folding the sample near the center while maintaining the configuration such that a transparent substrate 8-2 (PET film) was on the concave side (inside) and a substrate 9 (PI film) was on the convex side (outside). Here, when the number of folding reached 200,000 times, the test was terminated.

### <Presence or Absence of Peeling/Cracking>

⊙: No defects in the sample after 200,000 times or more folding (no problem in practical use)

∘: Presence of defects in the sample after 80,000 times to less than 200,000 times folding (no problem in practical use)

Δ: Presence of defects in the sample after 40,000 times to less than 80,000 times folding (no problem in practical use)

x: Presence of defects in the sample after less than 40,000 times folding (problem in practical use)

### <Evaluation of Amount of Deviation (Difference) in End Part>

As shown in FIG. 8, a sample laminate for a flexible image display device was cut into 2.5 cm×10 cm so that there was no deviation in the end part in an initial flat state (bending angle 0°), and the laminate was folded in the long side direction at a bending angle of 180° and a bending radius of 3 mm in a 25° C.×50% RH environment with a spacer (glass plate) having a thickness of 6 mm interposed therebetween, and pressed and fixed with a glass plate so that the space between the spacer and the laminate for a flexible image display device does not float. One hour after fixing, the amount of deviation (μm) (total amount of deviation of a plurality of pressure-sensitive adhesive layers) in the end part was measured using a microscope.

### <Evaluation of End Part Quality>

The end part of the sample folded by the above method was rubbed with a finger, and the adhesive stain and stickiness were evaluated based on the following criteria.

⊙: There are no adhesive stain and no stickiness in the end part of the sample (no problem in practical use)

∘: There is no adhesive stain in the end part of the sample, but there is a slight stickiness (no problem in practical use)

Δ: There is no adhesive stain in the end part of the sample, but there is a stickiness (no problem in practical use)

x: There are an adhesive stain and a stickiness in the end part of the sample (problem in practical use)

TABLE 2

| | | | | | | Mw of |
|---|---|---|---|---|---|---|
| | | | | | | polymer or |
| Polymer or | Monomer component (parts by weight) | | | | | oligomer |
| oligomer | BA | MA | HBA | HEA | AA | obtained |
| Polymer A1 | 99 | | 1 | | | 1.6 million |
| Polymer A2 | 94.9 | | | 0.1 | 5 | 2.2 million |
| Oligomer B1 | 95 | 3 | | | 2 | 4500 |

TABLE 3

| | | | | | | | | Properties of |
|---|---|---|---|---|---|---|---|---|
| | | | | | | | | pressure- |
| Type of | | | | | | | | sensitive |
| pressure- | | | | | | | | adhesive layer |
| sensitive | Polymer | | Crosslinking agent | | | Additive | | Storage elastic |
| adhesive | | Blending | (parts by weight) | | | | Blending | modulus G′ |
| layer | Type | amount | D110N | C/L | Peroxide | Type | amount | (25° C.) |
| P1 | A2 | 100 | | 0.6 | | | | 1.1.E+05 |
| P2 | A1 | 100 | 0.1 | | 0.3 | | | 8.1.E+04 |
| P3 | A1 | 100 | 0.02 | | 0.3 | B1 | 30 | 4.7.E+04 |
| P4 | A1 | 100 | 0.02 | | | B1 | 30 | 3.9.E+04 |
| P5 | A2 | 100 | | 15 | | | | 1.2.E+06 |

TABLE 4

| | | | | Pressure-sensitive adhesive layer | | |
|---|---|---|---|---|---|---|
| | | | | First | Second | Third |
| | Thickness | Thickness | Thickness | pressure- | pressure- | pressure- |
| | of | of | of | ensitive | sensitive | sensitive |
| | polarizing | retardation | protective | adhesive | adhesive | adhesive |
| | membrane | membrane | membrane | layer | layer | layer |
| | [μm] | [μm] | [μm] | Type | Type | Type |
| Example 1 | 5 | 7 | 20 | P1 | P1 | P1 |
| Example 2 | 5 | 7 | 20 | P2 | P2 | P2 |
| Example 3 | 5 | 7 | 20 | P3 | P3 | P3 |
| Example 4 | 5 | 7 | 20 | P3 | P3 | P3 |
| Comparative | 5 | 7 | 20 | P4 | P4 | P4 |
| Example 1 | | | | | | |
| Comparative | 5 | 7 | 20 | P5 | P5 | P5 |
| Example 2 | | | | | | |

Note) The thickness of each layer is the same in each Example (first pressure-sensitive adhesive layer: 50 μm, second pressure-sensitive adhesive layer: 70 μm, third pressure-sensitive adhesive layer: 50 μm).

TABLE 5

| | Bending | Amount of de- | |
|---|---|---|---|
| | resistance | viation at end | End part |
| | (continuous | part 25° C. × | quality |
| | bending) | 50% RH | 25° C. × |
| | test | [μm] | 50% RH |
| | φ6 mm | φ6 mm | — |
| Example 1 | ∘ | 261 | ⊙ |
| Example 2 | ∘ | 301 | ∘ |
| Example 3 | ∘ | 570 | Δ |
| Example 4 | ∘ | 540 | Δ |
| Comparative | ⊙ | 620 | x |
| example 1 | | | |
| Comparative | x | Sliding x | Not evaluable |
| example 2 | | | |

From the evaluation results in Table 5, it was confirmed in all Examples that the amount of deviation (in total) based on the pressure-sensitive adhesive layer in the end part of the laminate for a flexible image display device falls within a desired range, and there was no practical problem in cracking (breaking) and peeling in a bending resistance (continuous bending) test. It was also confirmed that the quality of the end part of the laminate was at a level that was practically acceptable by adjusting the amount of deviation (in total) of the pressure-sensitive adhesive layer to a desired range. That is, in the laminate for a flexible image display device according to each Example, by using a laminate for a flexible image display device having an amount of deviation (in total) based on the pressure-sensitive adhesive layer in the end part of the laminate in a desired range, it was confirmed that it is possible to obtain a laminate for a flexible image display device, which does not crack (break) or peel off due to repeated bending, has excellent bending resistance and adhesiveness, and has excellent end part quality free from adhesive stains and stickiness.

On the other hand, it was confirmed that in Comparative Example 1, the end part quality was inferior because the amount of deviation (in total) of the pressure-sensitive adhesive layer was out of the desired range. Further, in Comparative Example 2, since the amount of deviation (in total) of the pressure-sensitive adhesive layer was out of the desired range, a practically problematic level was confirmed in cracking (breaking) and peeling by the bending resistance (continuous bending) test. Further, it was confirmed that the bending resistance and adhesiveness were inferior, and the end part quality was also inferior. In particular, in Comparative Example 2, the storage elastic modulus G′ of the pressure-sensitive adhesive layer used was much higher than the preferred range, and the pressure-sensitive adhesive layer was not easily deformed during bending, and the amount of deviation (in total) of the pressure-sensitive adhesive layer immediately after bending was 80 μm, which was out of the desired range, so that the strain of each layer constituting the laminate for a flexible image display device could not be alleviated. As a result, the adhesiveness was also reduced, and the sliding (lateral sliding) between the pressure-sensitive adhesive layer and the other layers occurred. Thus, this was confirmed as being a practically problematic level.

### DESCRIPTION OF REFERENCE SIGNS

1 Polarizing membrane
2 Protective membrane
2-1 Protective membrane
2-2 Protective membrane
3 Retardation layer
4-1 Transparent conductive film
4-2 Transparent conductive film
5-1 Substrate film
5-2 Substrate film
6 Transparent conductive layer
6-1 Transparent conductive layer
6-2 Transparent conductive layer
7 Spacer
8 Transparent substrate
8-1 Transparent substrate (PET film)
8-2 Transparent substrate (PET film)
9 Substrate (PI film)
10 Organic EL display panel
10-1 Organic EL display panel (touch sensor attached)
11 Laminate for flexible image display devices (laminate for organic EL display devices)
12 Pressure-sensitive adhesive layer
12-1 First pressure-sensitive adhesive layer
12-2 Second pressure-sensitive adhesive layer
12-3 Third pressure-sensitive adhesive layer
13 Decorative printing film
14 Double sided tape
15 Glass plate for pressing
16 Spacer
17 Amount of deviation
20 Optical laminate
30 Touch panel
40 Window
100 Flexible image display device (organic EL display device)
P Bending point
UV Ultraviolet ray irradiation
L Liquid crystal material

1. A laminate for a flexible image display device, comprising a pressure-sensitive adhesive layer and an optical film including at least a polarizing membrane,
wherein an amount of deviation based on the pressure-sensitive adhesive layer in an end part of the laminate is 100 to 600 μm when the laminate is bent with a bending radius of 3 mm.

2. The laminate for a flexible image display device according to claim 1, wherein the pressure-sensitive adhesive layer has a storage elastic modulus G′ at 25° C. of 4×10⁴ to 8×10⁵ Pa.

3. The laminate for a flexible image display device according to claim 1, wherein the pressure-sensitive adhesive layer is formed of a pressure-sensitive adhesive composition containing a (meth)acrylic polymer.

4. The laminate for a flexible image display device according to claim 1, which has 2 or more and 5 or less layers of the pressure-sensitive adhesive layer.

5. A flexible image display device comprising the laminate for a flexible image display device according to claim 1 and an organic EL display panel, wherein the laminate for a flexible image display device is arranged on a viewing side with respect to the organic EL display panel.

6. The flexible image display device according to claim 5, wherein a window is arranged on a viewing side with respect to the laminate for a flexible image display device.
